(19) United States
(12) Patent Application Publication
(10) Pub. No.: US 2023/0264970 A1
(43) Pub. Date: Aug. 24, 2023

(54) COMPOSITIONS COMPRISING PEROVSKITE AND NON-PEROVSKITE

(71) Applicants: University of Notre Dame du Lac, South Bend, IN (US); Alliance for Sustainable Energy, LLC, Golden, CO (US)

(72) Inventors: Masaru KUNO, South Bend, IN (US); Michael BRENNAN, South Bend, IN (US); Anthony RUTH, South Bend, IN (US); Ilia PAVLOVETC, South Bend, IN (US); Jeffrey A. CHRISTIANS, Golden, CO (US); Taylor Hennessey MOOT, Golden, CO (US); Joseph Matthew LUTHER, Golden, CO (US)

(21) Appl. No.: 18/003,776

(22) PCT Filed: Jul. 2, 2021
(86) PCT No.: PCT/US21/40285

§ 371 Date: Dec. 29, 2022

Related U.S. Application Data
(60) Provisional application No. 63/047,426, filed on Jul. 2, 2020.

(51) Int. Cl. C01G 21/16; B05D 1/00; B05D 3/00; H10K 30/10; H10K 30/50

(52) U.S. Cl. CPC C01G 21/16; B05D 1/005; B05D 3/007; H10K 30/10; H10K 30/50; C01P 2002/34; B05D 2601/28

(57) ABSTRACT

Compositions comprise a perovskite and a non-perovskite. Perovskites comprise AₓA′_{y}A″_{(1-x-y)}BX₃, and non-perovskites may comprise A″, B and X, where A is a first cation, A′ is a second cation, A″ is a third cation, B is a fourth cation, X is an anion. In some instances, A, A′, and A″ are each independently (NH₂)₂CH⁺, CH₃NH₃⁺, Cs⁺, Rb⁺, or (NH₂)₂(C═NH₂)⁺, with the proviso that A, A′, and A″ are each different. The perovskite may have a first crystal structure in which the anion is corner-sharing, the non-perovskite may have a second crystal structure comprising at least one of an orthorhombic structure, a hexagonal structure, or a perovskite-like structure, and 1−x−y may be greater than about 0.15.

### CROSS-REFERENCE TO RELATED APPLICATION(S)

This application claims priority to U.S. Provisional Patent Application No. 63/047,426 filed on Jul. 2, 2020, the entire contents of which are incorporated herein by reference.

### GOVERNMENT INTEREST

This invention was made with government support under DE-SC0014334, DE-AC36-08GO28308, and DE-SC0014664, awarded by the Department of Energy, and under CHE1563528 awarded by the National Science Foundation. The government has certain rights in the invention.

### TECHNICAL FIELD

The present disclosure related to compositions comprising both perovskite and non-perovskite. Exemplary compositions may suppress ion migration.

### INTRODUCTION

Mixed cation and anion ABX₃-type halide perovskites (e.g., A=Cs⁺, Rb⁺, CH₃NH₃⁺ [MA⁺], and/or (NH₂)₂CH⁺[FA⁺], B=Pb⁺² or Sn⁺², and X⁻, =C⁻, Br⁻, or I⁻) have been used as light harvesters in solar cells. Perovskite solar cells with certified efficiencies up to 21% can be produced with solution-based processes, making the technology an attractive, inexpensive alternative to silicon.

### SUMMARY

In one aspect, a composition is disclosed. The composition may comprise a layer of formula (A)ₓ(A′)_{y}A″_{(1-x-y)}BX₃, the layer comprising a perovskite and a non-perovskite. A, A′, and A″ may comprise (NH₂)₂CH⁺, CH₃NH₃⁺, Cs⁺, Rb⁺, or (NH₂)₂(C═NH₂)⁺, with the proviso that A, A′, and A″ are each different. x+y is ≤0.85, B may be Pb⁺² or Sn⁺², and X₃ may comprise I⁻, Br⁻, Cl⁻, or combinations thereof.

In another aspect, a composition is disclosed. The composition may comprise a perovskite and a non-perovskite, where the perovskite comprises AₓA′_{y}A″_{(1-x-y)}BX₃, the non-perovskite comprises A″, B, and X, and A is a first cation, A′ is a second cation, A″ is a third cation, B is a fourth cation, X is an anion. The perovskite may have a first crystal structure in which the anion is corner-sharing, the non-perovskite may have a second crystal structure comprising at least one of an orthorhombic structure, a hexagonal structure, or a perovskite-like structure, and 1−x−y may be greater than about 0.15.

In another aspect, a solar cell is disclosed. The solar cell may comprise a composition comprising a layer of formula (A)ₓ(A′)_{y}A″_{(1-x-y)}BX₃, the layer comprising a perovskite and a non-perovskite. A, A′, and A″ may be each independently (NH₂)₂CH⁺, CH₃NH₃⁺, Cs⁺, Rb⁺, or (NH₂)₂(C═NH₂)⁺, with the proviso that A, A′, and A″ are each different. x+y is ≤0.85, B may be Pb⁺² or Sn⁺², and X₃ may comprise I⁻, Br⁻, Cl⁻, or combinations thereof.

### BRIEF DESCRIPTION OF THE DRAWINGS

FIGS. 1A-1C are schematic depictions of various aspects of an exemplary three-dimensional (3D) perovskite 100.

FIG. 2A shows a non-perovskite 2D-network structure.

FIG. 2B shows a non-perovskite 1D-network structure.

FIG. 2C shows a non-perovskite 0D-network structure.

FIG. 3A shows a crystal structure model of α-FAPbI_{3.}

FIG. 3B shows a crystal structure model of δₕₑₓ-FAPbI₃.

FIG. 3C shows a crystal structure model of δₒᵣₜₕₒ-CsPbI₃.

FIG. 3D shows powder X-Ray Diffraction (XRD) patterns for the mixed cation compositions FA_{0.85}Cs_{0.15}PbI₃, FA_{0.76}MA_{0.15}Cs_{0.0.9}PbI₃, and α/δ-FA_{0.33}MA_{0.33}Cs_{0.33}PbI₃, and simulated diffraction patterns for α-FAPbI₃, δₕₑₓ-FAPbI₃, and δₒᵣₜₕₒ-CsPbI₃. δₒᵣₜₕₒ-CsPbI₃ peaks are labeled δₒᵣₜₕₒ in the α/δ-FA_{0.33}MA_{0.33}Cs_{0.33}PbI₃ pattern.

FIGS. 4A-4C show computed E_{g}-values for the FAₓMA_{y}Cs_{1-x-y}PbI₃ compositional space and computed FAₓMA_{y}Cs_{1-x-y}PbI₃ composition-dependent ΔFₘᵢₓ-values.

FIG. 4A shows computed composition-dependent E_{g}-values for the FAₓMA_{y}Cs_{1-x-y}PbI₃ compositional space. Dashed lines represent corresponding isoenergetic fits (surface fit). The triangle (square) denotes the computed bandgap for FA_{0.85}Cs_{0.15}PbI₃ (FA_{0.76}MA_{0.15}Cs_{0.09}PbI₃). The circle (oval) indicates the computed bandgap for α-FA_{0.33}MA_{0.33}Cs_{0.33}PbI₃ (FA_{0.40-0.45}MA_{0.40-0.45}Cs_{0.10-0.20}PbI₃).

FIG. 4B shows linear absorption (solid lines) and emission spectra (dashed lines) for each of the mixed cation perovskites considered (FA_{0.85}Cs_{0.15}PbI₃, FA_{0.76}MA_{0.15}Cs_{0.0.9}PbI₃, and α/δ-FA_{0.33}MA_{0.33}Cs_{0.33}PbI₃).

FIG. 4C shows computed FAₓMA_{y}Cs_{1-x-y}PbI₃ composition-dependent ΔFₘᵢₓ-values. Dashed lines represent corresponding isoenergetic fits (surface fits).

FIGS. 5A-5I show infrared photothermal heterodyne imaging (IR-PHI) in comparison with conventional Fourier transform infrared (FTIR) spectroscopy as well as IR-PHI monitoring of bias-induced MA⁺ and FA⁺ migration for FA_{0.85}Cs_{0.15}PbI₃, FA_{0.76}MA_{0.15}Cs_{0.0.9}PbI₃, and α/δ-FA_{0.33}MA_{0.33}Cs_{0.33}PbI₃ lateral devices.

FIG. 5A shows FTIR (dashed line) and IR-PHI (solid line) spectra for a FA_{0.76}MA_{0.15}Cs_{0.09}PbI₃ lateral device with relevant FA⁺ and MA⁺ IR transitions labeled. Asterisks denote monitored FA⁺ and MA⁺ stretching/bending modes.

FIG. 5B shows a FA⁺1720 cm⁻¹ C═N stretching IR-PHI ratio map following biasing for a FA_{0.85}Cs_{0.15}PbI₃ lateral device.

FIG. 5C shows the associated (average) FA⁺ IR-PHI signal profile for a FA_{0.85}Cs_{0.15}PbI₃ lateral device.

FIG. 5D shows a FA⁺ IR-PHI ratio map for a FA_{0.76}MA_{0.15}Cs_{0.09}PbI₃ lateral device.

FIG. 5E shows a MA⁺ IR-PHI ratio map for a FA_{0.76}MA_{0.15}Cs_{0.09}PbI₃ lateral device.

FIG. 5F shows associated (average) IR-PHI signal profiles for FA⁺ (circles) and MA⁺ (diamonds) for a FA_{0.76}MA_{0.15}Cs_{0.09}PbI₃ lateral device.

FIG. 5G shows a FA⁺ ratio map for an α/δ-FA_{0.33}MA_{0.33}Cs_{0.33}PbI₃ lateral device.

FIG. 5H shows a MA⁺ ratio map for an α/δ-FA_{0.33}MA_{0.33}Cs_{0.33}PbI₃ lateral device.

FIG. 5I shows averaged IR-PHI signal profiles for an α/δ-FA_{0.33}MA_{0.33}Cs_{0.33}PbI₃ lateral device.

FIGS. 6A-6I show averaged ToF-SIMS intensity profiles for FA_{0.85}Cs_{0.15}PbI₃, FA_{0.76}MA_{0.15}Cs_{0.0.9}PbI₃, and α/δ-FA_{0.33}MA_{0.33}Cs_{0.33}PbI₃ lateral devices. Lateral device peak emission wavelengths (λ_{PL,max}) were mapped before and after 60 minutes of applied bias (4 V, |E|=0.1 V μm⁻¹) for FA_{0.85}Cs_{0.15}PbI₃, FA_{0.76}MA_{0.15}Cs_{0.09}PbI₃, and α/δ-FA_{0.33}MA_{0.33}Cs_{0.33}PbI₃.

FIG. 6A shows an averaged ToF-SIMS intensity profile of FA_{0.85}Cs_{0.15}PbI₃ before and after applied bias [FA⁺, MA⁺, and Cs⁺].

FIG. 6B shows an averaged ToF-SIMS intensity profile of FA_{0.76}MA_{0.15}Cs_{0.0.9}PbI₃ before and after applied bias [FA⁺, MA⁺, and Cs⁺].

FIG. 6C shows an averaged ToF-SIMS intensity profile of α/δ-FA_{0.33}MA_{0.33}Cs_{0.33}PbI₃. before and after applied bias [FA⁺, MA⁺, and Cs⁺].

FIG. 6D shows lateral device peak emission wavelengths a (λ_{PL,max}) mapped before 60 minutes of applied bias (4 V, |E|=0.1 V μm⁻¹) for FA_{0.85}Cs_{0.15}PbI₃.

FIG. 6E shows lateral device peak emission wavelengths a (λ_{PL,max}) mapped after 60 minutes of applied bias (4 V, |E|=0.1 V μm⁻¹) for FA_{0.85}Cs_{0.15}PbI₃.

FIG. 6F shows lateral device peak emission wavelengths (λ_{PL,max}) mapped before 60 minutes of applied bias (4 V, |E|=0.1 V μm⁻¹) for FA_{0.76}MA_{0.15}Cs_{0.09}PbI₃.

FIG. 6G shows lateral device peak emission wavelengths (λ_{PL,max}) mapped after 60 minutes of applied bias (4 V, |E|=0.1 V μm⁻¹) for FA_{0.76}MA_{0.15}Cs_{0.09}PbI₃.

FIG. 6H shows lateral device peak emission wavelengths (λ_{PL,max}) mapped before 60 minutes of applied bias (4 V, |E|=0.1 V μm⁻¹) for α/δ-FA_{0.33}MA_{0.33}Cs_{0.33}PbI₃.

FIG. 6I shows lateral device peak emission wavelengths (λ_{PL,max}) mapped after 60 minutes of applied bias (4 V, |E|=0.1 V μm⁻¹) for α/δ-FA_{0.33}MA_{0.33}Cs_{0.33}PbI₃.

FIGS. 7A-7D show solar cell stability tests (power conversion efficiency [PCE], open circuit voltages [V_{OC}], short circuit current densities [J_{SC}], and fill factors [FF]) conducted over the course of ˜11,000 minutes using ISOS-L-1 testing. In these measurements, unencapsulated solar cells are held under constant resistance (510Ω) with 77% simulated solar illumination, a constant temperature of ˜30° C., and a humidity between 20-30%.

FIG. 7A shows power conversion efficiency (PCE) measurements for FA_{0.76}MA_{0.15}Cs-_{0.09}PbI₃ (circles) and α/δ-FA_{0.33}MA_{0.33}Cs_{0.33}PbI₃ (diamonds) solar cells over ˜11,000 minutes of simulated solar illumination.

FIG. 7B shows short circuit current density (J_{SC}) measurements for FA_{0.76}MA_{0.15}Cs-_{0.09}PbI₃ (circles) and α/δ-FA_{0.33}MA_{0.33}Cs_{0.33}PbI₃ (diamonds) solar cells over ˜11,000 minutes of simulated solar illumination.

FIG. 7C shows open circuit voltage (V_{OC}) measurements for FA_{0.76}MA_{0.15}Cs_{0.09}PbI₃ (circles) and α/δ-FA_{0.33}MA_{0.33}Cs_{0.33}PbI₃ (diamonds) solar cells over ˜11,000 minutes of simulated solar illumination.

FIG. 7D shows fill factor measurements (FF) for FA_{0.76}MA_{0.15}Cs_{0.09}PbI₃ (circles) and α/δ-FA_{0.33}MA_{0.33}Cs_{0.33}PbI₃ (diamonds) solar cells over ˜11,000 minutes of simulated solar illumination.

FIGS. 8A-8C show FA_{0.85}Cs_{0.15}PbI₃, FA_{0.76}MA_{0.15}Cs_{0.09}PbI₃ and α/δ-FA_{0.33}MA_{0.33}Cs_{0.33}PbI₃ lateral devices, made by depositing mixed cation alloys atop interdigitated indium-doped tin oxide (ITO) electrodes with ˜40 μm channels.

FIG. 8A shows a photograph of a pre-patterned ITO substrate.

FIG. 8B shows a scanning electron microscopy (SEM) image of an actual perovskite lateral device.

FIG. 8C shows a zoomed-in SEM view of a single channel, where the dashed square indicates the approximate area of interest.

FIGS. 9A-9D show Rietveld fits (dashed lines) of an α/δ-FA_{0.33}MA_{0.33}Cs_{0.33}PbI₃ thin film XRD pattern (solid lines). Residual patterns are shown below the XRD pattern and fit. Asterisks denote contaminant (PbI₂) and ITO/glass substrate reflections.

FIG. 9A shows a Rietveld fit (dashed lines) of an α/δ-FA_{0.33}MA_{0.33}Cs_{0.33}PbI₃ thin film XRD pattern (solid lines), using x=1.0 (x′=0.17) for FAₓCs₁₋ₓPbI₃ (FA_{x′}Cs_{1-x′}PbI₃).

FIG. 9B shows a Rietveld fit (dashed lines) of an α/δ-FA_{0.33}MA_{0.33}Cs_{0.33}PbI₃ thin film XRD pattern (solid lines), using x=0.9 (x′=0.32) for FAₓCs₁₋ₓPbI₃ (FA_{x′}Cs_{1-x′}PbI₃).

FIG. 9C shows a Rietveld fit (dashed lines) of an α/δ-FA_{0.33}MA_{0.33}Cs_{0.33}PbI₃ thin film XRD pattern (solid lines), using x=0.80 (x′=0.47) for FAₓCs₁₋ₓPbI₃ (FA_{x′}Cs_{1-x′}PbI₃).

FIG. 9D shows a Rietveld fit (dashed lines) of an α/δ-FA_{0.33}MA_{0.33}Cs_{0.33}PbI₃ thin film XRD pattern (solid lines), using x=0.70 (x′=0.62) for FAₓCs₁₋ₓPbI₃ (FA_{x′}Cs_{1-x′}PbI₃).

FIG. 10 shows a representative cross-sectional scanning electron microscopy (SEM) image of an α/δ-FA_{0.33}MA_{0.33}Cs_{0.33}PbI₃ where an average perovskite active layer thickness is 500 nm.

FIGS. 11A-11F show representative 50×30 μm² SEM images of FA_{0.85}Cs_{0.15}PbI₃, FA_{0.76}MA_{0.15}Cs_{0.09}PbI₃, and α/δ-FA_{0.33}MA_{0.33}Cs_{0.33}PbI₃ lateral devices before and after biasing. Scale bars are 10 μm in all cases.

FIG. 11A shows a representative 50×30 μm² SEM image of a FA_{0.85}Cs_{0.15}PbI₃ lateral device before 60 minutes of applied bias (4V, |E|=0.1 V/μm).

FIG. 11B shows a representative 50×30 μm² SEM image of a FA_{0.85}Cs_{0.15}PbI₃ lateral device after 60 minutes of applied bias (4V, |E|=0.1 V/μm).

FIG. 11C shows a representative 50×30 μm² SEM image of a FA_{0.76}MA_{0.15}Cs_{0.09}PbI₃ lateral device before 60 minutes of applied bias (4V, |E|=0.1 V/μm).

FIG. 11D shows a representative 50×30 μm² SEM image of a FA_{0.76}MA_{0.15}Cs_{0.09}PbI₃ lateral device after 60 minutes of applied bias (4V, |E|=0.1 V/μm).

FIG. 11E shows a representative 50×30 μm² SEM image of a α/δ-FA_{0.33}MA_{0.33}Cs_{0.33}PbI₃ lateral device before 60 minutes of applied bias (4V, |E|=0.1 V/μm).

FIG. 11F shows a representative 50×30 μm² SEM image of a α/δ-FA_{0.33}MA_{0.33}Cs_{0.33}PbI₃ lateral device after 60 minutes of applied bias (4V, |E|=0.1 V/μm).

FIG. 12 shows DFT structures for FAPbI₃, MAPbI₃, and CsPbI₃.

FIG. 13 shows composition-dependent enthalpies of mixing for FAₓMA_{y}Cs_{1-x-y}PbI₃.

FIGS. 14A-14D show absolute PCE, J_{SC}, V_{OC}, and FF values for FA_{0.76}MA_{0.15}Cs_{0.09}PbI₃ and α/δ-FA_{0.33}MA_{0.33}Cs_{0.33}PbI₃ solar cells over ˜11,000 minutes of simulated solar illumination.

FIG. 14A shows absolute power conversion efficiency (PCE) values for FA_{0.76}MA_{0.15}Cs_{0.09}PbI₃ (circles) and α/δ-FA_{0.33}MA_{0.33}Cs_{0.33}PbI₃ (diamonds) solar cells over ˜11,000 minutes of simulated solar illumination.

FIG. 14B shows absolute short circuit current density (J_{SC}) values for FA_{0.76}MA_{0.15}Cs_{0.09}PbI₃ (circles) and α/δ-FA_{0.33}MA_{0.33}Cs_{0.33}PbI₃ (diamonds) solar cells over ˜11,000 minutes of simulated solar illumination.

FIG. 14C shows absolute open circuit voltage (V_{OC}) values for FA_{0.76}MA_{0.15}Cs_{0.09}PbI₃ (circles) and α/δ-FA_{0.33}MA_{0.33}Cs_{0.33}PbI₃ (diamonds) solar cells over ˜11,000 minutes of simulated solar illumination.

FIG. 14D shows absolute fill factor (FF) values for FA_{0.76}MA_{0.15}Cs_{0.09}PbI₃ (circles) and α/δ-FA_{0.33}MA_{0.33}Cs_{0.33}PbI₃ (diamonds) solar cells over ˜11,000 minutes of simulated solar illumination.

FIG. 15 shows PCE output tracking at maximum power point for FA_{0.76}MA_{0.15}Cs_{0.09}PbI₃ (circles) and α/δ-FA_{0.33}MA_{0.33}Cs_{0.33}PbI₃ (diamonds) solar cells. Stabilized power output is reached within the first 30 seconds of stability measurements.

FIGS. 16A-16D show representative PCE, J_{SC}, V_{OC}, and FF measurements for a CsPbI₃ solar cell over ˜9000 minutes of simulated solar illumination under N₂.

FIG. 16A shows representative power conversion efficiency (PCE) measurements for a CsPbI₃ solar cell over 9000 minutes of simulated solar illumination under N₂.

FIG. 16B shows representative short circuit current density (J_{SC}) measurements for a CsPbI₃ solar cell over ˜9000 minutes of simulated solar illumination under N₂.

FIG. 16C shows representative open circuit voltage (V_{OC}) measurements for a CsPbI₃ solar cell over ˜9000 minutes of simulated solar illumination under N₂.

FIG. 16D shows representative fill factor (FF) measurements for a CsPbI₃ solar cell over ˜9000 minutes of simulated solar illumination under N₂.

FIG. 17 shows a comparison of 1D Poisson modeling results and the experimental potential from KPFM measurements. Also shown are conduction and valence band potentials as well as the associated electric field profile.

### DETAILED DESCRIPTION

Before any embodiments of the disclosure are explained in detail, it is to be understood that the disclosure is not limited in its application to the details of construction and the arrangement of components set forth in the following description or illustrated in the following drawings. The disclosure is capable of other embodiments and of being practiced or of being carried out in various ways.

### I. Definitions

Unless otherwise defined, all technical and scientific terms used herein have the same meaning as commonly understood by one of ordinary skill in the art. In case of conflict, the present document, including definitions, will control. Methods and materials are described below, although methods and materials similar or equivalent to those described herein can be used in practice or testing of the present disclosure. All publications, patent applications, patents and other references mentioned herein are incorporated by reference in their entirety. The materials, methods, and examples disclosed herein are illustrative only and not intended to be limiting.

The terms “comprise(s),” “include(s),” “having,” “has,” “can,” “contain(s),” and variants thereof, as used herein, are intended to be open-ended transitional phrases, terms, or words that do not preclude the possibility of additional acts or structures. The singular forms “a,” “an” and “the” include plural references unless the context clearly dictates otherwise. The present disclosure also contemplates other embodiments “comprising,” “consisting of” and “consisting essentially of,” the embodiments or elements presented herein, whether explicitly set forth or not.

As used herein, the term “about” is used to indicate that exact values are not necessarily attainable. Therefore, the term “about” is used to indicate this uncertainty limit. The term “about” may refer to plus or minus 10% of the indicated number. For example, “about 10%” may indicate a range of 9% to 11%, and “about 1” may mean from 0.9-1.1. Other meanings of “about” may be apparent from the context, such as rounding off, so, for example “about 1” may also mean from 0.5-1.4. The modifier “about” should also be considered as disclosing the range defined by the absolute values of the two endpoints. For example, the expression “from about 2 to about 4” also discloses the range “from 2 to 4.”

The term “alkyl” means a straight or branched chain hydrocarbon. The term “C₁₋₄ alkyl” means a straight or branched chain hydrocarbon containing from 1 to 4 carbon atoms. Representative examples of alkyl include, but are not limited to, methyl, ethyl, n-propyl, iso-propyl, n-butyl, sec-butyl, iso-butyl, tent-butyl, n-pentyl, isopentyl, neopentyl, n-hexyl, 3-methylhexyl, 2,2-dimethylpentyl, 2,3-dimethylpentyl, n-heptyl, n-octyl, n-nonyl, and n-decyl.

The term “alkyl” may be preceded by a designation indicating the number of atoms present in the group in a particular instance (e.g., “C₁₋₄ alkyl,”). These designations are used as generally understood by those skilled in the art. For example, the representation “C” followed by a sub scripted number indicates the number of carbon atoms present in the group that follows. Thus, “C₃ alkyl” is an alkyl group with three carbon atoms (i.e., n-propyl, isopropyl). Where a range is given, as in “C₁₋₄,” the members of the group that follows may have any number of carbon atoms falling within the recited range. A “C₁₋₄alkyl,” for example, is an alkyl group having from 1 to 4 carbon atoms, however arranged (i.e., straight chain or branched).

The term “halogen” or “halo,” as used herein, means chlorine (Cl), bromine (Br), iodine (I), or fluorine (F).

The term “mixed anion,” as used herein refers to a compound comprising at least two different anions.

The term “mixed cation,” as used herein refers to a compound comprising at least two different cations.

The term “organic cation,” as used herein refers to a cation containing carbon. The cation may contain other elements, for example, the cation may contain hydrogen, nitrogen, or oxygen.

### II. Various Aspects of Exemplary Compositions

Broadly, exemplary compositions may comprise perovskite and non-perovskite. Various aspects of exemplary compositions, including descriptions of perovskites and non-perovskites, are discussed in the following sections.

### A. Components of Exemplary Compositions

### 1. Perovskites

Broadly, exemplary perovskites are of formula ABX₃ and have corner-sharing BX₆⁴⁻ octahedra with A-cations filling interstitial voids. These perovskites are commonly referred to as “three dimensional (3D)” perovskites.

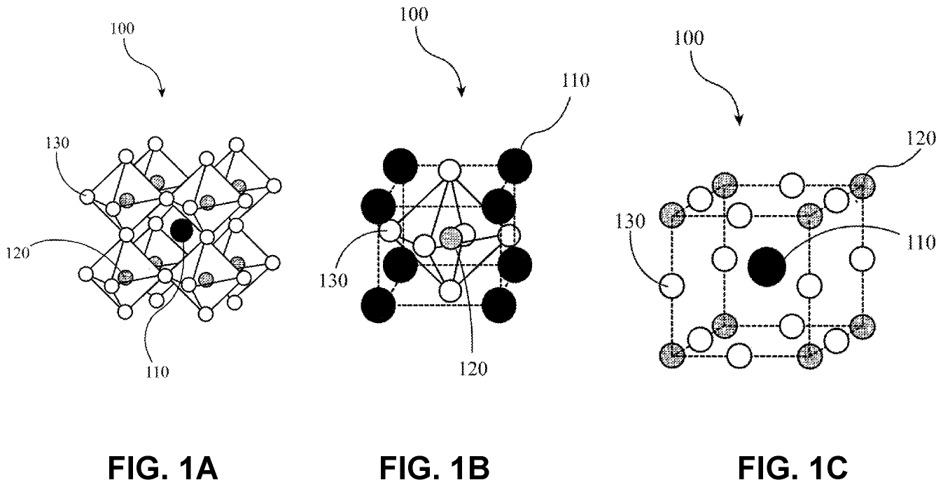

Example perovskites 100 are shown schematically in FIGS. 1A-1C. Perovskites 100 are 3D-perovskites that may organize into cubic crystalline structures with corner-sharing octahedra, as well as other crystalline structures such as tetragonal, and orthorhombic. Cubic, tetragonal, and orthorhombic 3D-perovskites are referred to as the alpha (α), beta (β), and gamma (γ) phases, respectively. The alpha (α), beta (β), and gamma (γ) crystallographic symmetries may be discerned by examining the X-ray Diffraction (XRD) diffraction pattern of the perovskite. Perovskites 100 may be described by the general formula ABX₃, where X (130) is an anion, A (110) is a monovalent cation, and B (120) is a divalent cation. A-cations are typically larger than B-cations. ABX₃ may be a mixed cation and/or a mixed anion. For example, in ABX₃, three different A-cations may be present (e.g., formamidinium (FA), methylammonium (MA), and cesium), and/or two different X-anions may be present (e.g., I⁻ and Br⁻).

FIG. 1A illustrates that a perovskite 100 may be organized into eight octahedra surrounding a central A-cation 110, where each octahedra is formed by six X-anions 130 surrounding a central B-cation 120.

FIG. 1B illustrates that a perovskite 100 may be visualized as a cubic unit cell, where the B-cation 120 is positioned at the center of the cube, an A-cation 110 is positioned at each corner of the cube, and an X-anion 130 is face-centered on each face of the cube.

FIG. 1C illustrates that a perovskite 100 may also be visualized as a cubic unit cell, where the B-cation 120 resides at the eight corners of a cube, while the A-cation 110 is located at the center of the cube and with 12 X-anions 130 centrally located between B-cations 120 along each edge of the unit cell. For both unit cells illustrated in FIGS. 1B and 1C, the A-cations 110, the B-cations 120, and the X-anions 130 balance to the general formula ABX₃, after accounting for the fractions of each atom shared with neighboring unit cells. For example, referring to FIG. 1B, the single B-cation 120 atom is not shared with any of the neighboring unit cells. However, each of the six X-anions 130 is shared between two-unit cells, and each of the eight A-cations 110 is shared between eight-unit cells. Therefore, for the unit cell shown in FIG. 1B, the stoichiometry simplifies to B=1, A=S*0.124=1, and X=6*0.5=3, or ABX₃.

### i. Example A-Cations

The A-cation 110 may include organic cations (e.g., an alkyl ammonium) and/or inorganic cations. Example inorganic A-cations 110 may include cesium (Cs), rubidium (Rb), potassium (K), sodium (Na), lithium (Li), and/or francium (Fr). Example organic A-cations 110 may be an alkyl ammonium cation, for example a C₁₋₂₀ alkyl ammonium cation, a C₁₋₆ alkyl ammonium cation, a C₂₋₆ alkyl ammonium cation, a C₁₋₅ alkyl ammonium cation, a C₁₋₄ alkyl ammonium cation, a C₁₋₃ alkyl ammonium cation, a C₁₋₂ alkyl ammonium cation, and/or a C₁ alkyl ammonium cation. Further examples of organic A-cations 110 include methylammonium (CH₃NH₃⁺), ethylammonium (CH₃CH₂NH₃⁺), propylammonium (CH₃CH₂CH₂NH₃⁺), butylammonium (CH₃CH₂CH₂CH₂NH₃⁺), formamidinium (NH₂CH═NH₂⁺), hydrazinium, acetylammonium, dimethylammonium, imidazolium, guanidinium and/or any other suitable nitrogen-containing or organic compound.

In other examples, an A-cation 110 may include an alkylamine. Thus, an A-cation 110 may include an organic component with one or more amine groups. For example, an A-cation 110 may be an alkyl diamine halide such as formamidinium (FA, CH(NH₂)₂⁺). Thus, the A-cation 110 may include an organic constituent in combination with a nitrogen constituent. In some cases, the organic constituent may be an alkyl group such as straight-chain or branched saturated hydrocarbon group having from 1 to 20 carbon atoms. An alkyl group may have from 1 to 6 carbon atoms. Examples of alkyl groups include methyl (C₁), ethyl (C₂), n-propyl (C₃), isopropyl (C₃), n-butyl (C₄), tert-butyl (C₄), sec-butyl (C₄), iso-butyl (C₄), n-pentyl (C₅), 3-pentanyl (C₅), amyl (C₅), neopentyl (C₅), 3-methyl-2-butanyl (C₅), tertiary amyl (C₅), and n-hexyl (C₆). Additional examples of alkyl groups include n-heptyl (C₇), n-octyl (C₈), and the like.

### ii. Example B-Cations

The B-cation 120 may be any 2+ valence state metal that can charge-balance the perovskite 100. B-cation examples include lead (Pb), tin (Sn), or germanium (Ge) in the in the 2+ state. Further examples include transition metals in the 2+ state such as manganese (Mn), magnesium (Mg), zinc (Zn), cadmium (Cd), and/or lanthanides such as europium (Eu). B-cations may also include elements in the 3+ valence state, as described below, including for example, Bi, La, and/or Y.

### iii. Example X-Anions

Examples for X-anions 130 include halogens. For instance, X-anions 130 may be fluorine, chlorine, bromine, iodine and/or astatine. In some cases, the perovskite halide may include more than one X-anion 130, for example pairs of halogens, chlorine and iodine, bromine and iodine, and/or any other suitable pairing of halogens. In other cases, the perovskite 100 may include two or more halogens of fluorine, chlorine, bromine, iodine, and/or astatine.

Thus, the A-cation 110, the B-cations 120, and X-anion 130 may be selected within the general formula of ABX₃ to produce a wide variety of perovskites 100, including, for example, methylammonium (MA) lead triiodide (CH₃NH₃PbI₃), and mixed halide perovskites such as CH₃NH₃PbI₃₋ₓClₓ and CH₃NH₃PbI₃₋ₓBrₓ. Thus, a perovskite 100 may have more than one halogen element, where the various halogen elements are present in non-integer quantities (e.g., x is not equal to 1, 2, or 3). As described herein, the A-cation 110 of a perovskite 100, may include one or more A-cations, for example, one or more of cesium, FA, MA, etc. Similarly, the B-cation 120 of a perovskite 100, may include one or more B-cations, for example, one or more of lead, tin, germanium, etc. Similarly, the X-anion 130 of a perovskite 100 may include one or more anions, for example, one or more halogens. Any combination is possible provided that the charges balance.

For example, a perovskite having the basic crystal structure illustrated in FIG. 1A, in at least one of a cubic, orthorhombic, and/or tetragonal structure, may have other compositions resulting from the combination of the cations having various valence states in addition to the 2+ state and/or 1+ state described above for lead and alkyl ammonium cations; e.g. compositions other than AB₂²⁺X₃ where A is one or more cations, or for a mixed perovskite where A is two or more cations. Thus, the methods described herein may be utilized to create novel mixed cation materials having the composition of a double perovskite (elpasolites), A₂B¹⁺B³⁺X₆, with an example of such a composition being Cs₂BiAgCl₆ and Cs₂CuBiI₆. Another example of a composition covered within the scope of the present disclosure is described by A₂B₄⁴⁺X₆, for example Cs₂PbI₆ and Cs₂SnI₆. Yet another example is described by A₃B₂³⁺X₉, for example Cs₃Sb₂I₉. For each of these examples, A is one or more cations, or for a mixed perovskite, A is two or more cations.

### 2. Non-Perovskites

Generally, exemplary non-perovskites may comprise (i) compositions of formula ABX₃ with face-sharing or edge-sharing BX₆⁴⁻ octahedra and/or (ii) perovskite halides having a two-dimensional (2D) network, a one-dimensional (1D) network and/or a zero-dimensional (0D) network, but not necessarily a formula ABX₃ (e.g. A₄BX₄, A₄BX₆, ABX₅). Exemplary non-perovskites may have a tetragonal, orthorhombic, or hexagonal crystal structures.

Many APbX₃ compositions do not form stable 3D-perovskite structures. In general, the perovskite framework collapses if the A-site cation is too large or too small for the 3D-network. As such, the compositional stability of 3D-perovskites may be predicted by the Goldschmidt Tolerance Factor equation:

$$t = \frac{{r}_{A} + {r}_{x}}{\sqrt{2} ( {r}_{B} + {r}_{X} )}$$

where r is the ionic radii of A⁺, B²⁺, and X⁻) when forming new mixtures. Empirically, t-values between 0.8<t<1.0 predict stable 3D perovskites. If t<0.8, however, then non-perovskite phases may form (Akkerman et al. ACS Energy Lett. 2020, 5, 604-610).

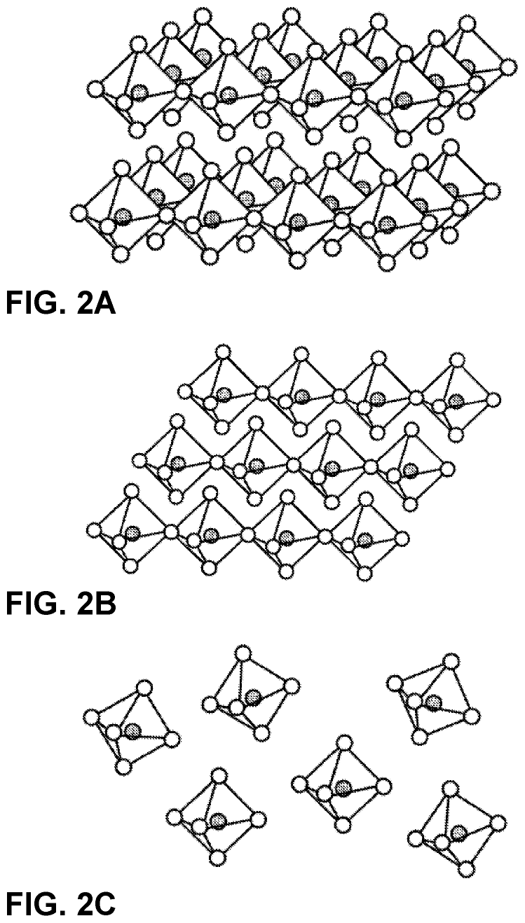

If too unstable to form a 3D-perovskite, perovskite halides can form a two-dimensional (2D) network, a one-dimensional (1D) network and/or a zero-dimensional (0D) network, possessing the same unit structure. These 2D, 1D, and 0D-perovskites are FIGS. 2A-2C illustrates a 2D-network, a 1D-network, and a 0D-network, in FIG. 2A, FIG. 2B, and FIG. 2C, respectively. As described above and depicted in FIGS. 1A-1C, a 3D perovskite may adopt a general chemical formula of ABX₃, in which the A-cation may be a monovalent cation (e.g., methylammonium and/or formamidinium CH(NH₂)₂⁺), the B-cation may be a divalent cation (e.g., Pb²⁺ and/or Sn²⁺), and the X-anion may be a halide anion (I⁻, Br⁻, and/or Cl⁻). In this formula, the 3D network of perovskites may be constructed by linking all corner sharing BX₆ octahedra, with the A-cation filling the space between eight octahedral unit cells to balance the crystal charge.

Referring to FIG. 2A, through the chemically accomplished dimensional reduction of the 3D crystal lattice, 2D perovskites, (A′)ₘ(A)ₙ₋₁BₙX₃ₙ₋₁, may adopt a new structural and compositional dimension, A′ (not shown), where monovalent (m=2) or divalent (m=1) cations can intercalate between the X-anions of the 2D perovskite sheets. Referring to FIG. 2B, 1D perovskites are constructed by BX₆ octahedral chained segments spatially isolated from each other by surrounding bulky organic cations (not shown), leading to bulk assemblies of paralleled octahedral chains. Referring to FIG. 2C, typically, the 0D perovskites are constructed of isolated inorganic octahedral clusters and surrounded by small cations (not shown) which are connected via hydrogen bonding.

### 3. Stoichiometric Amounts of Anions

Exemplary compositions comprise perovskite and non-perovskite, and may be defined by the formula:

(A)ₓ(A′)_{y}A″_{(1-x-y)}BX₃,

where A is a first A-cation, A′ is a second A-cation, A″ is a third A-cation, B is a B-cation, and X is an X-anion as defined and described above.

Relative stoichiometric amounts of A, A′, and A″ may be defined by subscripts x and y. Typically, a sum of x and y is no greater than 0.85. In various instances, a sum of x and y is between about 0.15 to 0.85; about 0.20 to about 0.80; about 0.40 to about 0.80; about 0.60 to about 0.85; about 0.6 to about 0.7; about 0.63 to about 0.69; about 0.7 to about 0.85; or about 0.80 to about 0.85. In various instances, a sum of x and y is at least 0.15; at least 0.20; at least 0.25; at least 0.40; at least 0.50; at least 0.60; at least 0.70; at least 0.75; or at least 0.80. In various instances, a sum of x and y is no greater than 0.85; no greater than 0.80; no greater than 0.75; no greater than 0.70; no greater than 0.60; no greater than 0.50; no greater than 0.40; or no greater than 0.25.

A stoichiometric amount of the A-cation may be defined by subscript x. Typically, x is between about 0.20 to about 0.6. In various instances x is between about 0.2 and about 0.55; about 0.2 and 0.5; about 0.25 to about 0.45; about 0.3 to about 0.4; or about 0.3 to about 0.36. In various instances x is at least 0.20; at least 0.25; at least 0.30; at least 0.35; at least 0.40; at least 0.45; at least 0.50; or at least 0.55. In various instances x is no greater than 0.60; no greater than 0.55; no greater than 0.50; no greater than 0.45; no greater than 0.40; no greater than 0.35; no greater than 0.30; or no greater than 0.20.

A stoichiometric amount of the A′-cation may be defined by subscript y. Typically, y is between about 0.20 to about 0.6. In various instances y is between about 0.2 and about 0.55; about 0.2 and 0.5; about 0.25 to about 0.45; about 0.3 to about 0.4; or about 0.3 to about 0.36. In various instances, y is at least 0.20; at least 0.25; at least 0.30; at least 0.35; at least 0.40; at least 0.45; at least 0.50; or at least 0.55. In various instances y is no greater than 0.60; no greater than 0.55; no greater than 0.50; no greater than 0.45; no greater than 0.40; no greater than 0.35; no greater than 0.30; or no greater than 0.20.

### 4. Relative Amounts of Perovskite and Non-Perovskite

Exemplary compositions may have various ratios of perovskite to non-perovskite. For example, a composition may comprise between about 5% to about 50% non-perovskite by volume. In various instances, exemplary compositions may comprise, by volume, between about 5% and about 50%; about 10% and about 45%; about 20% and about 40%; about 5% and about 25%; about 25% and about 50%; or about 40% to about 50% non-perovskite. In various instances, exemplary compositions may comprise, by volume, no more than 50%; no more than 45%; no more than 40%; no more than 35%; no more than 30%; no more than 25%; no more than 20%; no more than 15%; or no more than 10% non-perovskite. In various instances, exemplary compositions may comprise, by volume, at least 5%; at least 10%; at least 20%; at least 25%; at least 30%; at least 35%; at least 40%; or at least 45% non-perovskite.

### B. Physical Aspects of Exemplary Compositions

### 1. Stabilizing Effect of Mixed Cations

The long-term stability of perovskite compositions has been an obstacle, particularly in halide perovskite solar cells (PSC). The implementation of mixed cation compositions has helped address some of the instability issues, especially since methylammonium (MA), a volatile and moisture sensitive species, has often been attributed as an unstable component of the prototypical MAPbI₃ formula. Although it has been observed that replacing some of the MA cation with either formamidinum (FA) or cesium (Cs) alleviates the volatility issues, the stability of the corner sharing octahedral perovskite can consequently suffer. For example, pure FAPbI₃ tends to favor a hexagonal non-perovskite with edge sharing PbI₆⁴⁻ octahedra, whereas pure CsPbI₃ favors a non-perovskite orthorhombic with face sharing octahedra. Compositional mixing (e.g., mixing FA and Cs) to achieve ideal “average A-site radius values” that tune the tolerance factor has helped mitigate some of these phase stability issues to achieve shelf-stable compositions. However, despite the success of the more-complex mixed cation compositions, these materials can be susceptible to de-mixing and phase segregation into more pure compositions.

### 2. Cation Migration/Segregation

Exemplary compositions may suppress or prevent cation migration/segregation. Electric field-induced ion migration in perovskite solar cells is of particular concern because it results in current-voltage (J-V) hysteresis, metastable power conversion efficiencies (PCEs) and accelerated active layer degradation. Facile ion migration within the perovskite lattice stems from relatively fragile ionic bonding between heavy, low-valence ions. This ion migration results in small activation barriers and correspondingly moderate diffusion coefficients for halide anions and A-site cations. The mobile nature of A⁺ cations and X⁻ anions is thus an instability of all metal halide perovskites. While numerous studies have focused on halide migration and segregation, less investigation has been directed to cation migration in metal halide perovskites, especially regarding double- and triple-cation FAₓMA_{y}Cs_{1-x-y}Pb X₃ alloys.

APbX₃-type perovskites are constructed through corner-sharing PbX₆⁴⁻ octahedra with A⁺ cations that fill their interstitial voids to act as steric stabilizers. APbX₃-type perovskites assume either perfect cubic symmetry (i.e., perovskite α-phase) or lower symmetry, distorted perovskite phases (e.g., the MAPbI₃ tetragonal β-phase). In some compositions, thermodynamically stable but photovoltaically undesirable non-perovskite phases exist, entailing either face-sharing PbX₆⁴⁻ octahedra with hexagonal symmetry (e.g., δₕₑₓ-FAPbI₃) or edge-sharing PbX₆⁴⁻ octahedra with orthorhombic symmetry (e.g., δₒᵣₜₕₒ-CsPbI₃). Although FAPbI₃ and CsPbI₃ prefer to adopt non-perovskite phases, they can be stabilized in photovoltaically-desired α-phases by alloying with FA⁺, MA⁺ and Cs⁺. This results in double- and triple-cation systems (e.g., FA_{0.85}Cs_{0.15}PbI₃ and FA_{0.76}MA_{0.15}Cs_{0.09}PbI₃) that exhibit improved stability relative to corresponding single cation systems. Mixed cation materials have therefore been at the forefront of perovskite solar cell research.

However, working devices remain subject to the destabilizing effects of ion migration. A⁺ in both FA_{0.85}Cs_{0.15}PbI₃ and FA_{0.76}MA_{0.15}Cs_{0.09}PbI₃ solar cells has been observed to undergo perovskite α-phase/non-perovskite δ-phase segregation via in situ X-ray diffraction measurements under simulated solar illumination. Specifically, perovskite phase active layers partially separate into δₒᵣₜₕₒ-CsPbI₃ and δₕₑₓ-FAPbI₃ phases. α/δ phase segregation is concurrent with degraded solar cell performance. This observation as well as prior investigations link A⁺ migration/segregation to solar cell performance/stability, further highlighting the importance of understanding and preventing cation migration/segregation in perovskite solar cells.

### 3. Exemplary Layer Thickness

Exemplary compositions may have various thicknesses. For example, a thickness of a composition deposited as a film or layer may be between about 200 nm and 800 nm. In various instances, a composition thickness may be between about 200 nm and 800 nm; about 300 nm and about 700 nm; about 400 nm and about 600 nm; about 200 nm and about 400 nm; about 400 nm and about 600 nm; or about 600 nm and about 800 nm. In various instances, a composition thickness may be at least 200 nm; at least 300 nm; at least 400 nm; at least 500 nm; at least 600 nm; or at least 700 nm. In various instances, a composition thickness may be no greater than 800 nm; no greater than 700 nm; no greater than 600 nm; no greater than 500 nm; no greater than 400 nm; or no greater than 300 nm.

### III. Example Articles of Manufacture

### A. Optoelectronic Devices

The optoelectronic device of the disclosed technology may be a photovoltaic device, a photodiode, a phototransistor, a photomultiplier, a photo resistor, a photo detector, a light-sensitive detector, solid-state triode, a battery electrode, a light-emitting device, a light-emitting diode, a transistor, a solar cell, a laser, or a diode injection laser. Usually, the optoelectronic device of the invention is a photovoltaic device. More usually, the device is a solar cell.

The optoelectronic may be an optoelectronic device comprising a first electrode, a second electrode, and, disposed between the first and second electrodes, the mixed perovskite and non-perovskite composition described herein.

The selection of the first and second electrodes of the optoelectronic devices may depend on the structure type. Typically, an electron transport layer (ETL) is deposited onto a tin oxide, more typically onto a fluorine-doped tin oxide (FTO) anode, which is usually a transparent or semi-transparent material. Thus, the first electrode is usually transparent or semi-transparent and typically comprises FTO. Usually, the thickness of the first electrode is from 200 nm to 600 nm, more usually, from 300 to 500 nm. For instance, the thickness may be 400 nm. Typically, FTO is coated onto a glass sheet. Usually, the second electrode comprises a high work function metal, for instance gold, silver, nickel, palladium or platinum, and typically silver. Usually, the average thickness of the second electrode is from 50 nm to 250 nm, more usually from 100 nm to 200 nm. For instance, the thickness of the second electrode may be 150 nm.

### B. Physical Properties of Articles of Manufacture

Short-circuit current density (J_{SC}) open-circuit voltage (V_{OC}), and fill-factor (FF) are all parameters, that in combination, enable determination of the efficiency (power conversion efficiency, PCE) of an optoelectronic device (e.g., a solar cell).

Power Conversion Efficiency (PCE) is a measure of the ratio of the energy output from a device over the energy input from the light source (e.g., the sun).

J_{SC} is the current through a device when the voltage across the device is zero (e.g., when the device is short-circuited).

The open circuit voltage (V_{OC}) is the maximum voltage available from a solar cell, when there is no current.

The fill Factor (FF) is a parameter which, in conjunction with open circuit voltage (V_{OC}) and short circuit current (I_{SC}), determines the maximum power from a solar cell. The FF parameter is used to determine efficiency.

### IV. Example Methods of Manufacture

### A. Film Preparation

Mixed perovskite and non-perovskite films, may be prepared by first forming a precursor solution with ionic compounds comprising the desired cations (e.g., FA⁺, MA⁺, Cs⁺, and Pb⁺²) and anions (X⁻) for the film (e.g., FAX, MAX, CsX, and PbX₂, where X=I, Br, or Cl) in an anhydrous solvent (e.g., dimethyl formamide (DMF) or dimethyl sulfoxide (DMSO)) or an anhydrous solvent mixture (e.g., 1:1 DMF:DMSO). This precursor solution may then be deposited onto a substrate (e.g., fluorine-doped tin oxide (FTO), indium-doped tin oxide (ITO), tin oxide (TiO₂) glass) via spin coating. The subsequent perovskite mixture is then annealed on the substrate at a high temperature (e.g., 100° C. or higher) to form the final mixed perovskite and non-perovskite film.

### B. Solar Cell Preparation

Exemplary solar cells may be prepared using example compositions disclosed herein using various techniques known in the art. For instance, a method may include forming a mixed perovskite and non-perovskite film on an electron-transport layer (ETL), wherein the ETL is atop a substrate (e.g., titanium oxide), then depositing a hole-transport layer (HTL) on the mixed perovskite and non-perovskite film. The solar cell may include, in order, a transparent conducting oxide substrate, an electron-transport layer on the transparent conducting oxide substrate, a mixed perovskite and non-perovskite film on the electron-collecting layer, and a hole-transport layer on the mixed perovskite and non-perovskite film. The electron-transport layer may be fluorine-doped titanium oxide (TiO₂). The hole-transport layer may be spiro-OMeTAD.

### V. EXPERIMENTAL EXAMPLES

The foregoing may be better understood by reference to the following examples, which are presented for purposes of illustration and are not intended to limit the scope of the technology.

### Abbreviations

g=gram(s)
mg=milligram(s)
μg=microgram(s)
v/v=volume per volume
m=meter(s)
μm=micrometer(s)
s=second(s)
h, hr=hour(s)
min=minute(s)
rpm=revolution(s) per minute
W=watt(s)
mW=milliwatt(s)
V=volt(s)
eV=electronvolt(s)
meV=millielectronvolt(s)
   |E|=dielectric strength
DMSO=dimethylsulfoxide
DMF=dimethylformamide
MA=methylammonium (CH₃NH₃⁺)
FA=formamidinium (CH(NH₂)₂⁺)
MAI=methylammonium iodide (CH₃NH₃I)
FAI=formamidinium iodide (CH(NH₂)₂I)
PEDOT: PSS=poly(3,4-ethylenedioxythiophene) polystyrene sulfonate
PMMA=poly(methyl-methacrylate)
spiro-OMeTAD=2,2′,7,7′-tetrakis(N,N-di-p-methoxyphenylamino)-9,9′-spirobifluorene
PCBM=phenyl-C61-butyric acid methyl ester
TBP=4-tert-butylpyridine
TAA=titanium diisopropoxide bis(acetylacetonate)
Co[t-BuPyPz]₃[TFSI]₃=tris(2-(1H-pyrazol-1-yl)-4-tert-butylpyridine)cobalt(III)
tri[bis(trifluoromethane)sulfonimide]
XRD=X-Ray Diffraction
DFT=Density Functional Theory
IR-PHI=Infrared Photothermal Heterodyne Imaging
FTIR=Fourier Transform Infrared
ToF-SIMS=Time-of-Flight Secondary Ion Mass Spectrometry
PL=photoluminescence
PCE=power conversion efficiency
J_{SC}=short circuit current density
V_{OC}=open circuit voltage
FF=fill factor
V_{bias}=applied bias
LiTFSI=bis(trifluoromethane)sulfonimide lithium
UV=ultraviolet
SEM=Scanning Electron Microscopy
KPFM=Kelvin Probe Force Microscopy
ITO=indium-doped tin oxide
FTO=fluorine-doped tin oxide
E_{g}=band gap
ΔFₘᵢₓ=free energy of mixing
ΔE=energy change s
ΔH=change in enthalpy of a system in a reaction
ETL=electron transport layer
HTL=hole transport layer

Materials. Various materials were used in the following examples. Methylammonium iodide [CH₃NH₃I, MAI], formamidinium iodide [CH(NH₂)₂I, FAI]and the cobalt complex Co[t-BuPyPz]₃[TFSI]₃ (FK209) were purchased from Dyesol. Lead (II) iodide (99.9985% metals basis, PbI₂) was purchased from Alfa Aesar. 2,2′,7,7′-tetrakis(N,N-di-p-methoxyphenylamino)-9,9′-spirobifluorene (spiro-OMeTAD) was purchased from Lumtec. PEDOT: PSS (Al 4083) and PCBM were purchased from Ossila. All other chemicals [Cesium iodide (99.999%, CsI), 4-tert-butylpyridine (TBP), titanium diisopropoxide bis(acetylacetonate) (TAA), dimethylformamide (99.8%, anhydrous, DMF), dimethylsulfoxide (≥99.9%, anhydrous, DMSO), chlorobenzene (99.8%, anhydrous)] were purchased from Sigma-Aldrich.

### Example 1: Mixed Cation Thin Film Preparation and Lateral Device Fabrication

### a) Perovskite and Hybrid Perovskite Preparation

### i. FA_{0.76}MA_{0.15}Cs_{0.09}PbI₃

Ternary cation films were formed using a precursor solution containing 172 mg FAI (1.0 mmol), 600 mg PbI₂ (1.3 mmol), 31.8 mg MAI (0.2 mmol) (1:1.3:0.2 overall mole ratio) and 80 μL of a 1.5 M CsI stock solution in DMSO, diluted with 1 mL of DMF/DMSO (4:1 v/v). The solution was deposited onto substrates by spin-coating with the following program: 1000 rpm, 10 s; 6000 rpm, 20 s. With approximately 6 seconds remaining in the program, 0.1 mL of chlorobenzene was rapidly dispensed onto spinning films, forming uniform, orange films. Films were subsequently annealed on a hotplate at 100° C. for 60 minutes.

### ii. FA_{0.85}Cs_{0.15}PbI₃

Binary cation films were formed from a precursor solution containing 461 mg of PbI₂ (1.0 mmol), 39.0 mg CsI (0.15 mmol), 146.2 mg FAI (0.85 mmol), and 1 mL of DMF/DMSO (7:3 v/v).1 This solution was deposited onto substrates by spin-coating, using the following program: 100 rpm, 5 s; 3000 rpm, 10 s; 5000 rpm, 30 s. With approximately 10 s remaining in the program, 1.0 mL of toluene was rapidly dispensed onto spinning films. The films were subsequently annealed on a hotplate at 170° C. for 15 minutes.

### iii. α/δ-FA_{0.33}MA_{0.33}CS_{0.33}PbI₃

Ternary cation films were formed using a precursor solution containing 56.8 mg FAI (0.33 mmol), 461 mg PbI₂ (1.0 mmol), 52.5 mg MAI (0.33 mmol), 85.8 mg CsI (0.33 mmol), and 1 mL of DMF/DMSO (7:3 v/v). Solutions were deposited onto substrates by spin-coating with the same spinning procedure as for the FA_{0.76}MA_{0.15}Cs_{0.09}PbI₃ films, but at 8 s remaining in the program, 0.2 mL of ethyl acetate was dispensed over ˜2 s onto spinning films, forming uniform, brown films. The films were subsequently annealed on a hotplate at 100° C. for 60 minutes.

For all hybrid perovskite films, a thin protective layer of poly(methyl-methacrylate) (PMMA) [Sigma-Aldrich, Mw=120,000] was spin-coated onto them from a 30 mg/mL solution of PMMA in chlorobenzene at 2000 rpm for 30 s.

### b) Lateral Device Fabrication and Perovskite Film Deposition

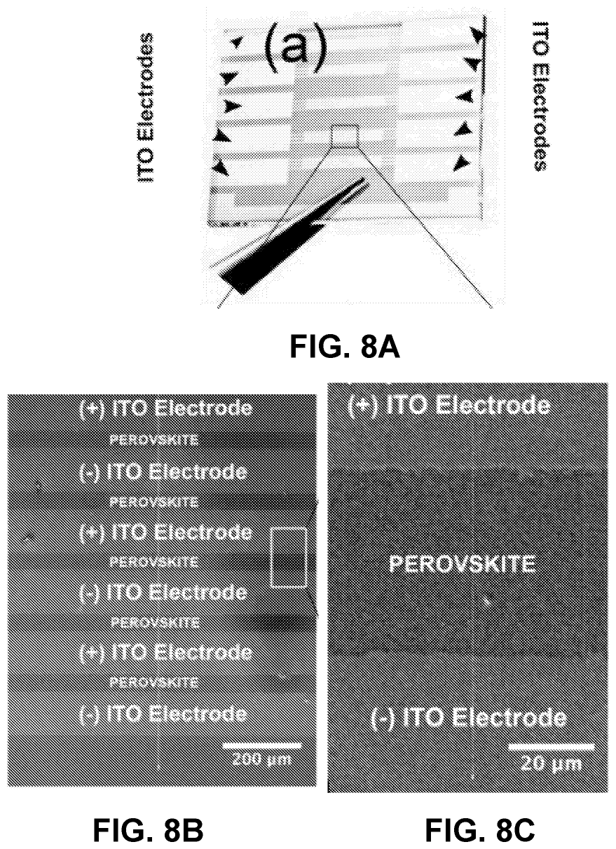

FA_{0.85}Cs_{0.15}PbI₃, FA_{0.76}MA_{0.15}Cs_{0.09}PbI₃ and α/δ-FA_{0.33}MA_{0.33}Cs_{0.33}PbI₃ lateral devices were made by depositing mixed cation alloys atop interdigitated indium-doped tin oxide (ITO) electrodes with ˜40 μm channels. Pre-patterned ITO substrates (FIGS. 8A-8C) with 40 μm spacings between contacts were first washed in isopropanol, then cleaned 2 by UV-ozone treatment for 5 minutes. Perovskite layer deposition methods were specific to cation composition. All perovskite precursor preparation and film deposition were carried out under inert atmosphere.

### Example 2: X-ray Diffraction (XRD) Pattern Analysis

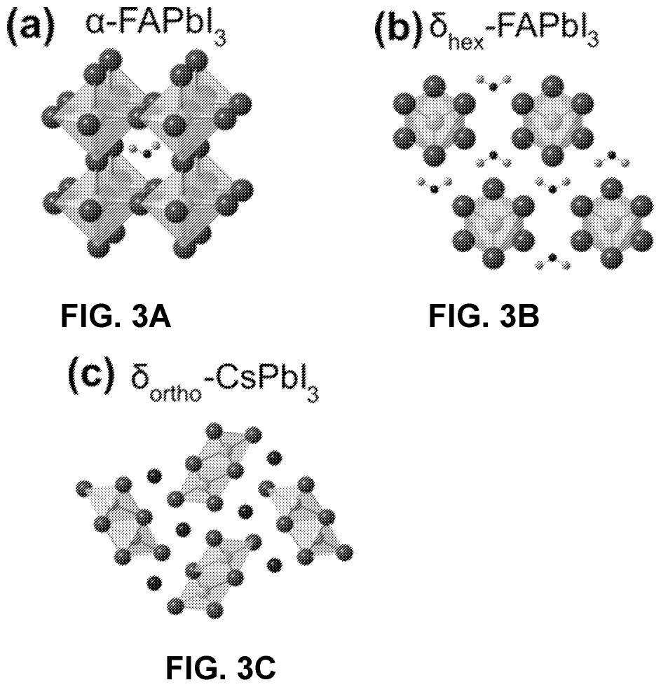

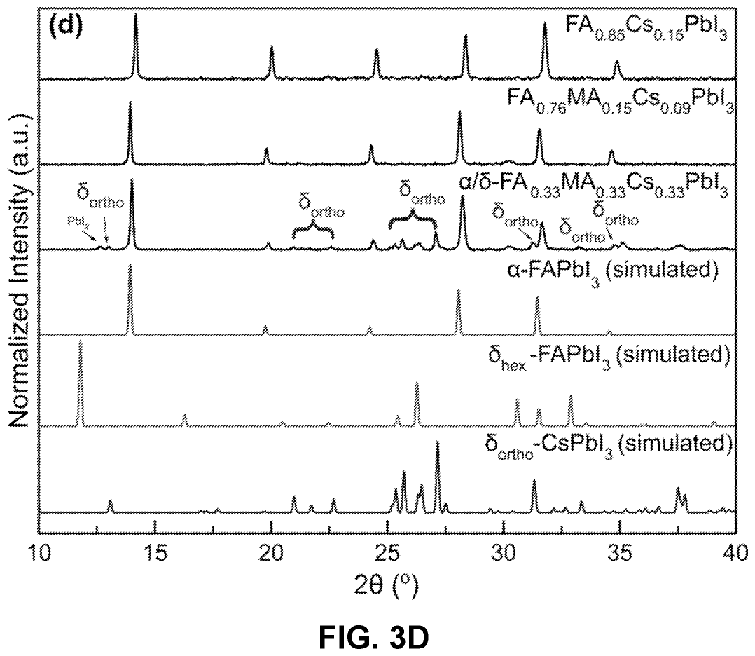

Powder X-ray diffraction (XRD) patterns for FA_{0.85}Cs_{0.15}PbI₃, FA_{0.76}MA_{0.15}Cs_{0.09}PbI₃ and α/δ-FA_{0.33}MA_{0.33}Cs_{0.33}PbI₃ lateral devices were obtained and analyzed (FIGS. 3A-3D). Below the experimental data are simulated XRD patterns for α-FAPbI₃, δₕₑₓ-FAPbI₃, and δₒᵣₜₕₒ-CsPbI₃ (FIGS. 3A-3D). The FA_{0.85}Cs_{0.15}PbI₃ and FA_{0.76}MA_{0.15}Cs_{0.09}PbI₃ devices appear to adopt exclusive α-phase structures. By contrast, α/δ-FA_{0.33}MA_{0.33}Cs_{0.33}PbI₃ exhibits characteristic reflections of both α-FAₓMA_{y}Cs_{1-x-y}PbI₃ and δₒᵣₜₕₒ-CsPbI₃, which arises from the inability to incorporate large amounts of Cs+into cubic, FA-rich perovskites, due to cation size mismatches. No δₕₑₓ-FAPbI₃ is observed in pristine α/δ-FA_{0.33}MA_{0.33}Cs_{0.33}PbI₃ films. The α/δ-FA_{0.33}MA_{0.33}Cs_{0.33}PbI₃ pattern shows δₒᵣₜₕₒ-phase (α-phase) reflections shifted to lower (higher) angles by approximately 0.08° (0.06°)2θ. This suggests lattice expansion (contraction) as compared to pure δₒᵣₜₕₒ-CsPbI₃ (α-phase FA_{0.76}MA_{0.15}Cs_{0.09}PbI₃). δₒᵣₜₕₒ-CsPbI₃ expansion may stem from inclusion of small amounts of FA⁺ and MA⁺ into its lattice whereas α-phase contraction results from Cs⁺ and MA⁺ enrichment in α-phase FAₓMA_{y}Cs_{1-x-y}PbI₃.

### Example 3: Ritveld Refinement of α/δ-FA_{0.33}MA_{0.33}Cs_{0.33}PbI₃

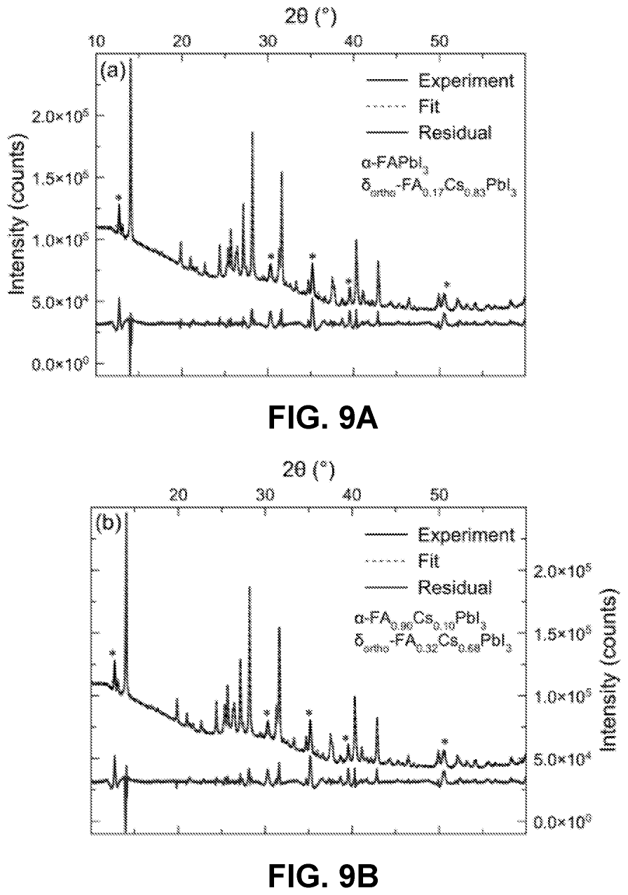

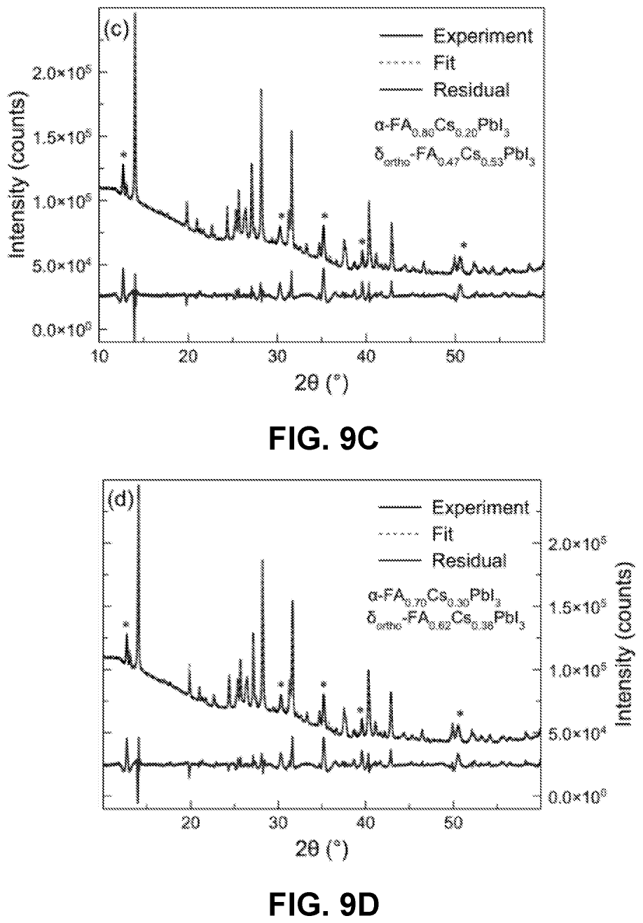

To estimate the relative amounts of δₒᵣₜₕₒ-CsPbI₃ and α-phase FAₓMA_{y}Cs_{1-x-y}PbI₃ in α/δ-FA_{0.33}MA_{0.33}Cs_{0.33}PbI₃ Rietveld refinement of the XRD pattern of α/δ-FA_{0.33}MA_{0.33}Cs_{0.33}PbI₃ (FIG. 3D) was performed. Refinement was conducted using FAₓCs₁₋ₓPbI₃ models for each phase given that the above-mentioned XRD peak shifting indicates cation alloying. For simplicity, FA⁺ in FAₓCs₁₋ₓPbI₃ models represents equivalent amounts of FA⁺ and MA⁺, due to their weak scattering efficiencies and because XRD signals are dominated by Cs⁺, Pb²⁺ and I⁻ scattering. Moreover, a range of α-phase and δₒᵣₜₕₒ-phase FAₓCs₁₋ₓPbI₃ compositions (x=1 to x=0) is surveyed and their associated χ² parameters compared to estimate optimal cation compositions for each phase. TABLE 1 shows results of the Rietveld refinement (FIGS. 9A-9D) shows a representative fit), including assumed cation compositions for each phase, calculated α/δₒᵣₜₕₒ-phase ratios, and resulting χ²-values.

TABLE 1
Rietveld refinement results for α/δ-FA_{0.33}MA_{0.33}Cs_{0.33}PbI₃

| x, | x′, | | | |
|---|---|---|---|---|
| FAₓCs₁₋ₓPbI₃ | FA_{x′}Cs_{1-x′}PbI₃ | χ² | FAₓCs₁₋ₓPbI₃ | FA_{x′}Cs_{1-x′}PbI₃ |
| 1.00 | 0.17 | 97.9 | 62 | 38 |
| 0.90 | 0.32 | 92.5 | 61 | 39 |
| 0.80 | 0.47 | 91.7 | 61 | 39 |
| 0.70 | 0.62 | 94.8 | 60 | 40 |
| 0.60 | 0.77 | 150 | Fit diverges | Fit diverges |
| 0.50 | 0.92 | 169 | Fit diverges | Fit diverges |

For α-phase (δₒᵣₜₕₒ-phase) FAₓCs₁₋ₓPbI₃, best fit x-values range from 0.80-0.90 (0.32-0.47). The corresponding composition of α/δ-FA_{0.33}MA_{0.33}Cs_{0.33}PbI₃ is therefore estimated to be 39% δₒᵣₜₕₒ-phase (FA_{0.16-0.24}MA_{0.16-0.24}Cs_{0.52-0.68}PbI₃) and 61% α-phase (FA_{0.40-0.45}MA_{0.40-0.45}Cs_{0.1-0.2}PbI₃). Additionally, Goldschmidt tolerance factors (t) of α-phase compositions range from t=0.97-0.98 and predict cubic symmetry, in agreement with FIG. 3D.

### Rietveld Refinement Method

Relative amounts of α-FAₓMA_{y}Cs_{1-x-y}PbI₃ and δₒᵣₜₕₒ-CsPbI₃ phases in α/δ-FA_{0.33}MA_{0.33}Cs_{0.33}PbI₃ were estimated via Rietveld refinement of its XRD pattern. Quantitative analysis was performed using FullProf Suite software (EdPCR 2.0 fit routine). Integrated intensities were approximated during refinement using mixtures of mixed cation crystal structure models, representing both α-FAₓMA_{y}Cs_{1-x-y}PbI₃ and δₒᵣₜₕₒ-CsPbI₃. Specifically, α/δ-FA_{0.33}MA_{0.33}Cs_{0.33}PbI₃ was approximated as a binary mixture of α-phase FAₓCs₁₋ₓPbI₃ and δₒᵣₜₕₒ-phase FA_{x′}Cs_{1-x′}PbI₃. In both FAₓCs₁₋ₓPbI₃ and FA_{x′}Cs_{1-x′}PbI₃, FA⁺ represents equivalent amounts of FA⁺ and MA⁺ given that they are effectively X-ray equivalent due to similar, weak scattering efficiencies and because observed XRD signals are dominated by Cs⁺, Pb²⁺, and I⁻ scattering. The FAₓCs₁₋ₓPbI₃ (FA_{x′}Cs_{1-x′}PbI₃) model was constructed by adding partial Cs⁺ (FA⁺) occupancy into pure α-FAPbI₃ (δₒᵣₜₕₒ-CsPbI₃) crystal structure models. FAₓCs₁₋ₓPbI₃ x-values were varied from 1.0 to 0.5. x′-values for FA_{x′}Cs_{1-x′}PbI₃ were calculated for a given FAₓCs₁₋ₓPbI₃ composition using the following constraint: A[FAₓCs₁₋ₓPbI₃]+B[FA_{x′}Cs_{1-x′}PbI₃]=α/δ-FA_{0.66}Cs_{0.33}PbI₃, where A and B are fractions of each phase. Nominal A and B-values were estimated from a preliminary Rietveld refinement of the α/δ-FA_{0.33}MA_{0.33}Cs_{0.33}PbI₃ XRD pattern using single cation α-FAPbI₃ and δₒᵣₜₕₒ-CsPbI₃ crystal structure models. This yields A and B estimates of A=0.6 and B=0.4, which are subsequently used along with x to find x′.

### Example 4: Density Functional Theory (DFT) Calculations

Computational, density functional theory (DFT) calculations were performed to observe cation alloying and conversely their segregation/de-mixing in mixed cation perovskites under external perturbation. Here, for both binary and triple-cation perovskites, full DFT structural relaxations include the possibility of cation disorder as well as PbI₆⁴⁻ octahedral reorientation, typically associated with tetragonal β-phases. Forty-five DFT calculations were conducted to span the full ternary compositional space.

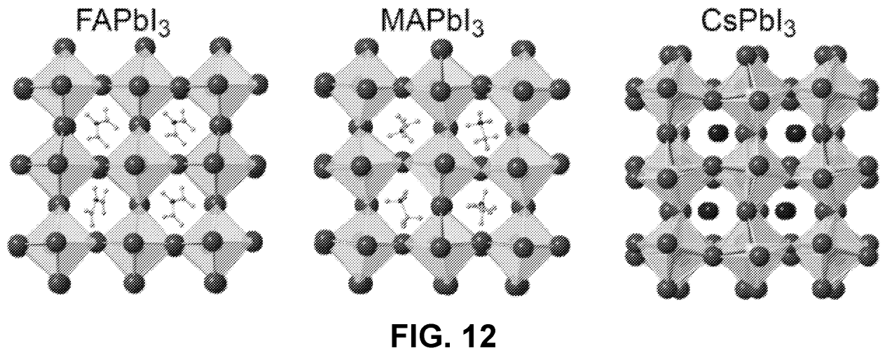

All simulations commence from structures having random cation orientations. To generate such structures, α-CsPbI₃ is first relaxed and expanded to a 2×2×2 supercell. Random Cs ions are then replaced with FA⁺ and MA⁺ to achieve desired stoichiometries. Ionic positions along with supercell shape and volume are subsequently relaxed using the conjugate gradient method until energy differences between steps are less than 0.01 eV. All calculations are performed with an 8×8×8 Monkhorst-Pack gamma-centered k-point mesh. Structures having less than half the A-site cations being Cs undergo a cubic to tetragonal (β-phase) transition involving tilting of PbI₆⁴⁻ octahedra. Symmetry breaking, provided by FA⁺ and MA⁺ dipole orientations, may drive this structural transition. Structures are then allowed to re-relax. For systems not undergoing an α→β transition, I⁻ ions are randomly displaced by distances up to 0.1 angstroms. All theoretical disordered structures possessed reduced energies relative to corresponding cubic, α-phase structures (CsPbI₃: ΔE=111 meV/formula unit, FAPbI₃ ΔE=165 meV/formula unit, MAPbI₃: ΔE=44 meV/formula unit). The resulting optimized post DFT relaxation structures for FAPbI₃, MAPbI₃, and CsPbI₃ reveal PbI₆⁴⁻ octahedral rotation (FIG. 12). Even α-phase FAₓMA_{y}Cs_{1-x-y}PbI₃ systems possess octahedral disorder, connected to FA or MA orientation.

### Example 5: Calculated Bandgap (E_{g}) and Associated Free Energies for Cation Mixing (ΔFₘᵢₓ)

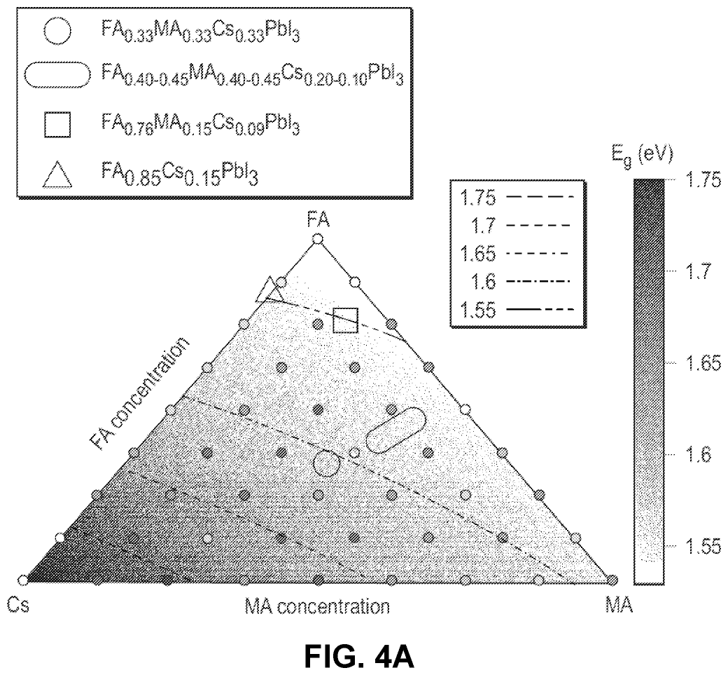

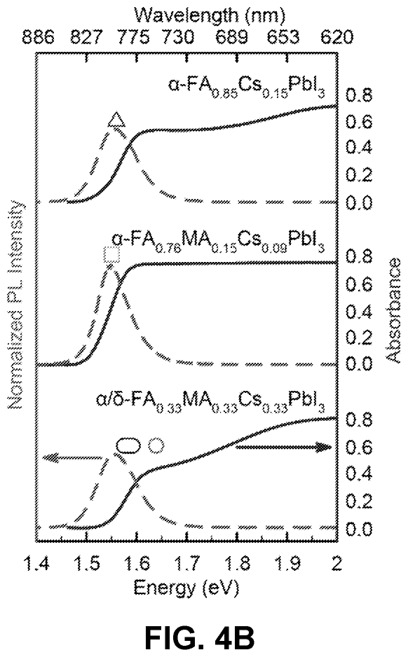

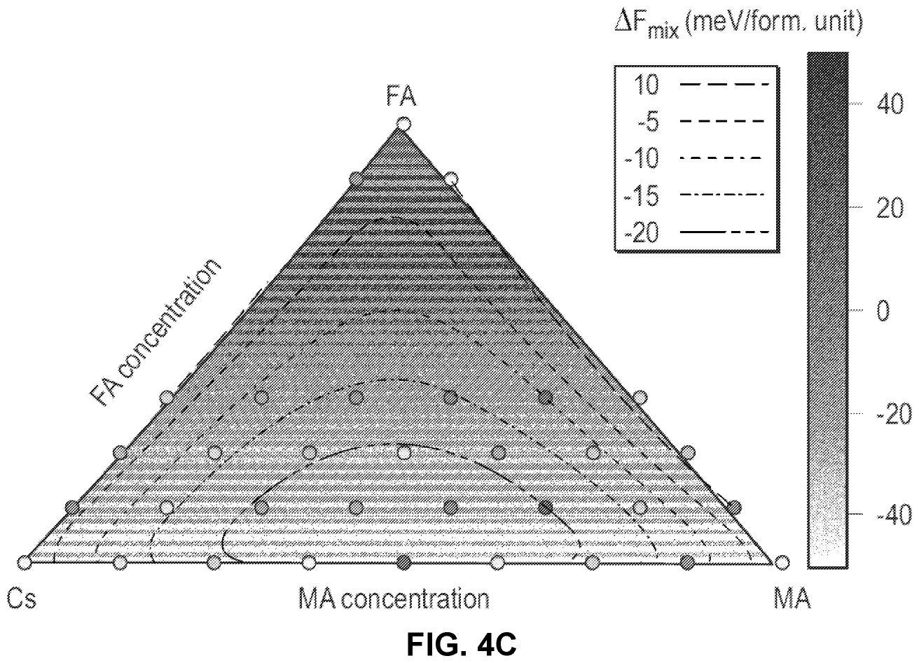

Calculated bandgaps (E_{g}) for limiting (i.e. CsPbI₃, FAPbI₃, and MAPbI₃) compositions agree with experimental E_{g}-values [CsPbI₃: calculated (experiment) 1.80 (1.75) eV; MAPbI₃ calculated (experiment) 1.61 (1.59) eV; FAPbI₃: calculated (experiment) 1.52 (1.53) eV]. The modeling further shows that FAₓMA_{y}Cs_{1-x-y}PbI₃ E_{g}-values empirically vary linearly with average A-site cation radius [r_{A}(Å)=x r_{FA}+y r_{MA}+(1−x−y) r_{Cs} or equivalently with Goldschmidt tolerance factor] as E_{g} (eV)=−0.256r_{A}+2.177 (FIG. 4A).

The modeling further shows E_{g}-values to agree with the band edge energies of FA_{0.85}Cs_{0.15}PbI₃ and FA_{0.76}MA_{0.15}Cs_{0.09}PbI₃ (FIGS. 4A-4B). For α/δ-FA_{0.33}MA_{0.33}Cs_{0.33}PbI₃, the previously discussed Rietveld refinement structural analysis suggests a triple-cation stoichiometry between FA_{0.4}MA_{0.4}Cs_{0.2}PbI₃ (E_{g}=1.61 eV) and FA_{0.45}MA_{0.45}Cs_{0.1}PbI₃ (E_{g}=1.58 eV). In this case, theory (black oval in FIGS. 4A-4B) compares better to experiment, corroborating claims of δₒᵣₜₕₒ-CsPbI₃ inclusions in parent α/δ-FA_{0.33}MA_{0.33}Cs_{0.33}PbI₃ films.

Reliable DFT structures across the FAₓMA_{y}Cs_{1-x-y}PbI₃ compositional space enable subsequent estimates of associated free energies (ΔFₘᵢₓ) for cation mixing via equation (1).

x FAPbI₃+y MAPbI₃+(1−x−y) CsPbI₃ [symbol] FAₓMA_{y}Cs_{1-x-y}PbI₃ (1)

where mixing estimates include the Shannon compositional entropy but do not consider phase transitions incurred above certain Cs concentrations of order 1−x−y=0.3.

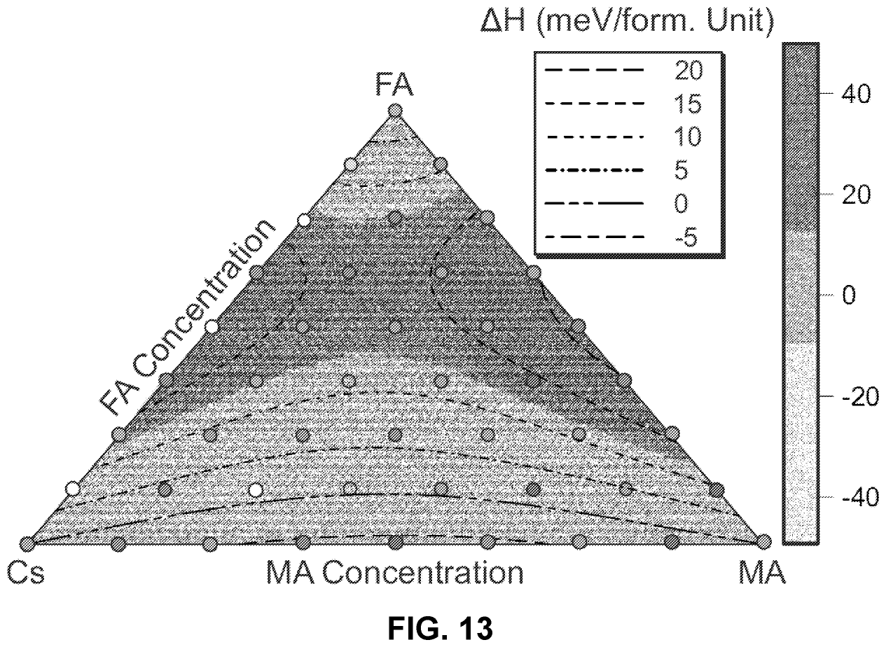

These calculations indicate that the majority of ΔFₘᵢₓ is entropic in origin with minor enthalpic contributions, between −5 and 15 meV/formula unit (FIG. 13). FIG. 4C plots ΔFₘᵢₓ and shows that it is generally negative across the triple-cation compositional space with values between −5 and 40 meV/formula unit. These relatively small ΔFₘᵢₓ values indicate that cation mixing and, by extension, de-mixing, are equally favored, rationalizing why application of an external perturbation may induce cation migration in FAₓMA_{y}Cs_{1-x-y}PbI₃.

### Kelvin Probe Force Microscopy (KPFM) Method

Kelvin Probe Force Microscopy (KPFM) measurements use a commercial atomic force microscope (AFM, Veeco Dimension 5000 AFM and Nanoscope V controller system) housed in an Ar-filled glovebox. Overall topography and KPFM potential measurements are recorded simultaneously with an external Kelvin Probe Control Unit (Omicron, Kelvin Probe CU) and an external high-frequency lock-in amplifier (Signal Recovery, 7280 DSP). Topography is measured in tapping mode at the first resonance frequency (50-70 kHz) of the conductive Pt/Ir coated AFM tip (Nanosensors, PPP-EFM). A 300-500 kHz AC modulation at the AFM tip's 2^{nd} resonance is also added to measure associated tip/sample electrostatic potentials. Contact potentials are nullified using a DC bias applied to the probe tip.

### Example 6: Infrared Photothermal Heterodyne Imaging (IR-PHI) Evaluation of Bias-Induced Cation Migration in Lateral Devices

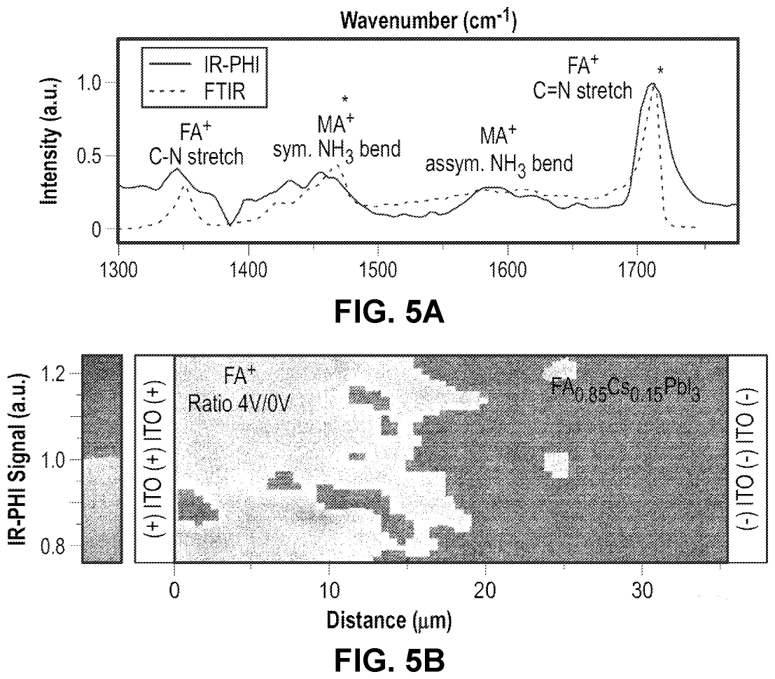

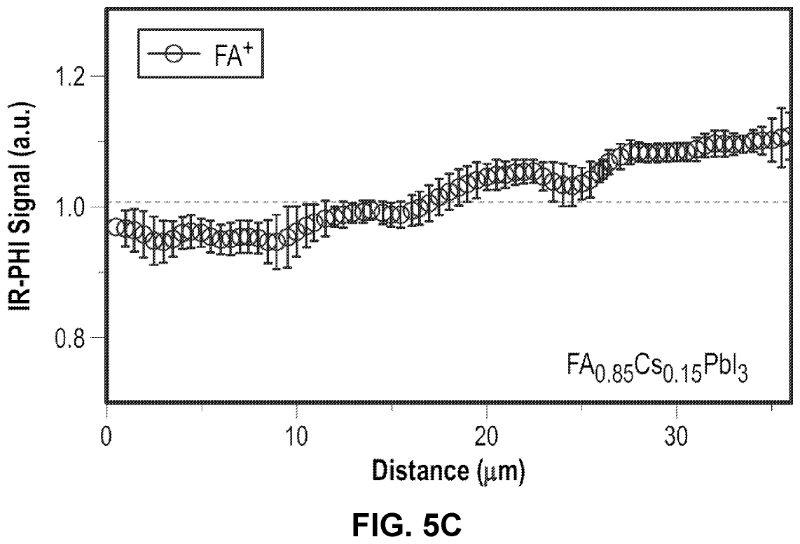

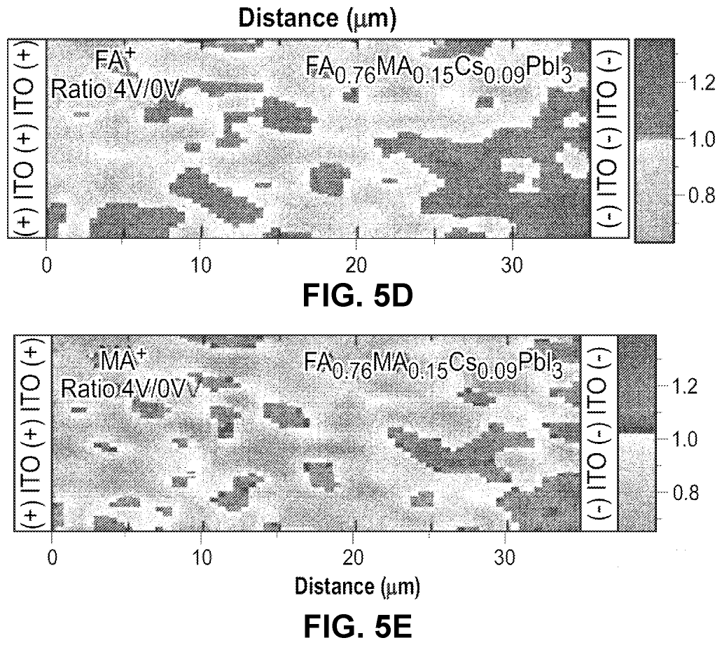

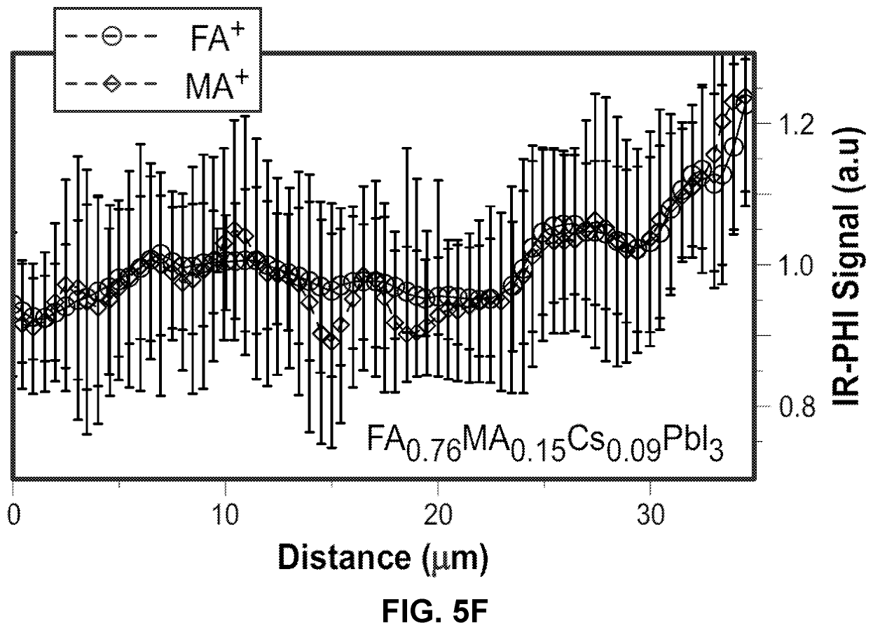

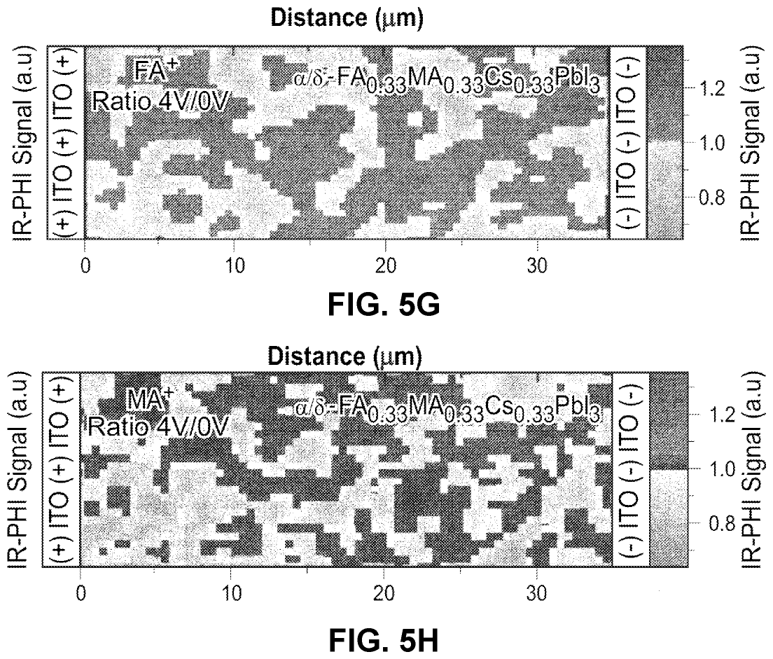

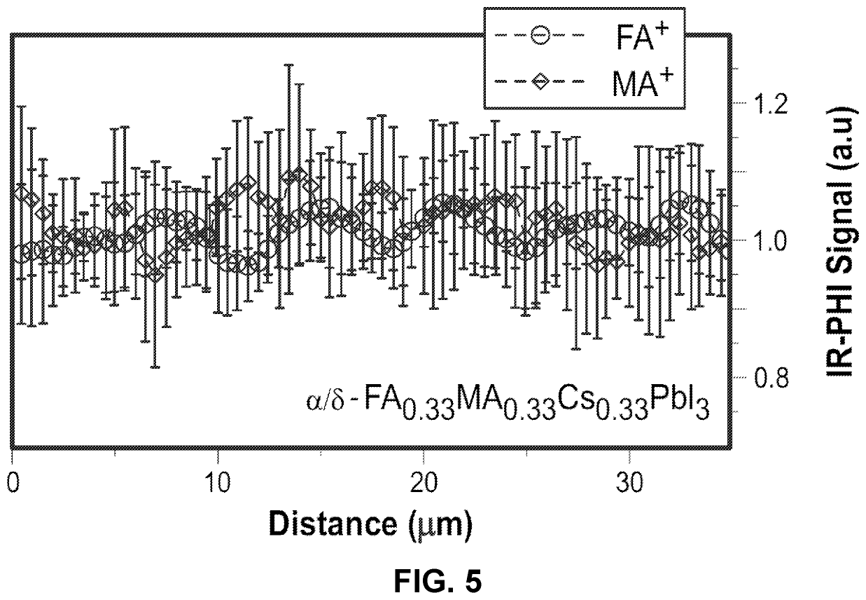

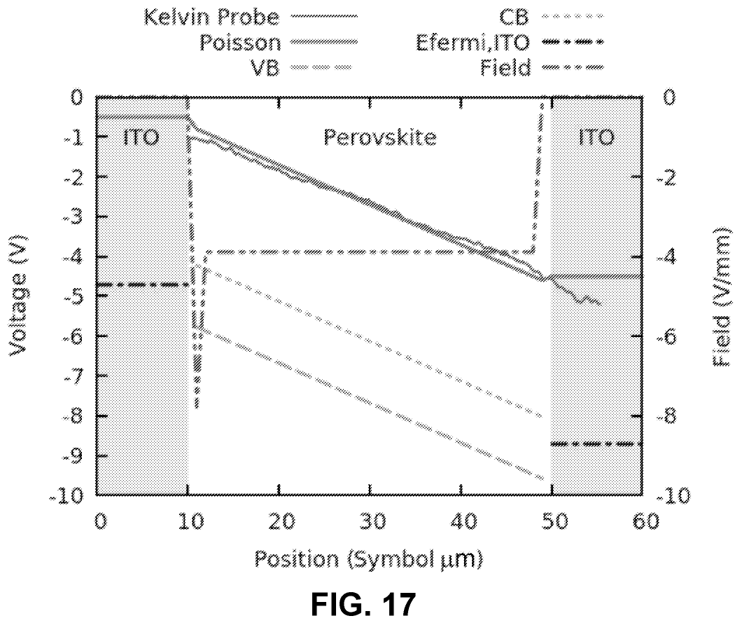

To survey the relative stabilities of FA_{0.85}Cs_{0.15}PbI₃, FA_{0.76}MA_{0.15}Cs_{0.09}PbI₃ and α/δ-FA_{0.33}MA_{0.33}Cs_{0.33}PbI₃ against bias-induced cation migration, infrared photothermal heterodyne imaging (IR-PHI) is used to monitor bias-induced MA⁺ and FA⁺ migration in lateral devices. The spectral fidelity of IR-PHI was established by comparing an acquired (local) FA_{0.76}MA_{0.15}Cs_{0.09}PbI₃ absorption spectrum to that from conventional Fourier transform infrared (FTIR) spectroscopy (FIG. 5A). Asterisks in FIG. 5A denote monitored spectral energies. Selective IR-PHI monitoring of FA⁺ and MA⁺ is realized by measuring the absorption of the FA⁺ (MA⁺) C═N stretching (NH₃ symmetric bending) mode at 1720 cm⁻¹ (1450 cm⁻¹). Cation migration is induced in lateral devices by applying a bias (V_{bias}=4 V, |E|=0.1 V μm⁻¹) to their electrodes. Associated 1D Poisson modeling (FIG. 17) suggests linear potential drops across channels, as corroborated by Kelvin probe force microscopy measurements (FIG. 17).

The FA⁺ and MA⁺ IR-PHI maps between ITO electrodes (˜20×35 μm² areas) are acquired before and after 60 minutes of biasing. Ratio maps are then generated by dividing post-bias maps with initial maps to visualize cation movement. IR-PHI ratios greater (lesser) than 1 indicate accumulation (depletion) of FA⁺ and/or MA⁺. These ratio maps also account for local film thickness variations.

FIG. 5B illustrates the resulting FA⁺ IR-PHI ratio map for FA_{0.85}Cs_{0.15}PbI₃. There are clear spatial heterogeneities evident in FA⁺ concentration across the film. Dark (light) areas near negative (positive) ITO electrodes correlate to FA⁺ accumulation (depletion) after biasing. FIG. 5C shows the associated (average) FA⁺ IR-PHI signal profile with the horizontal, dashed grey line indicating an ideal signal ratio of 1. FIG. 5C also reports local standard deviations from averaged FA⁺ IR-PHI signals across a vertical column of pixels. Accumulation (depletion) of FA⁺ at the lateral device negative (positive) electrode is thus apparent in the double-cation system.

FIGS. 5D-5E show corresponding FA⁺ and MA⁺ IR-PHI ratio maps for a FA_{0.76}MA_{0.15}Cs_{0.09}PbI₃ lateral device. Here, FA⁺ and MA⁺ accumulate at the negative ITO electrode, as indicated by the light-shaded areas on the right-hand sides of FIGS. 5D-5E Simultaneous decreases in FA⁺ and MA⁺ IR-PHI signals near positive electrodes (left-hand side of each map) indicate corresponding depletion of both cations. FIG. 5F plots average FA⁺ (circles) and MA⁺ (diamonds) line profiles that illustrate this behavior.

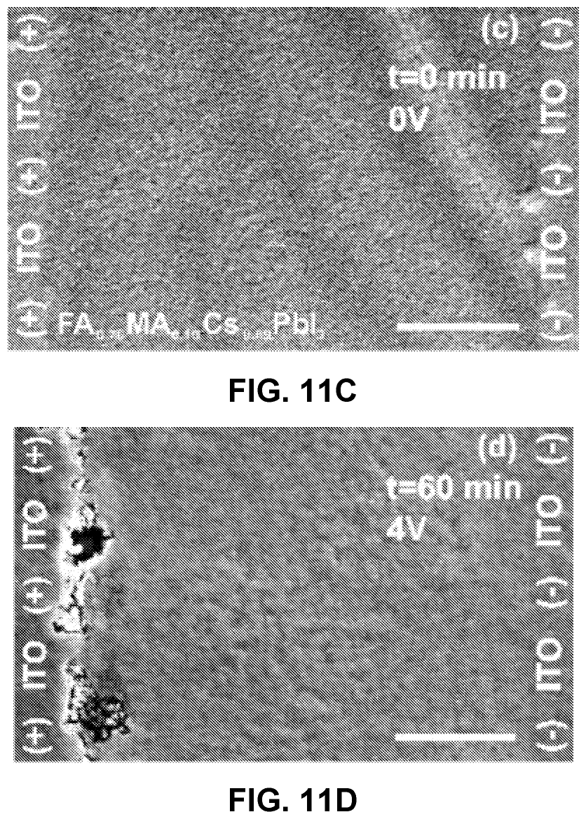

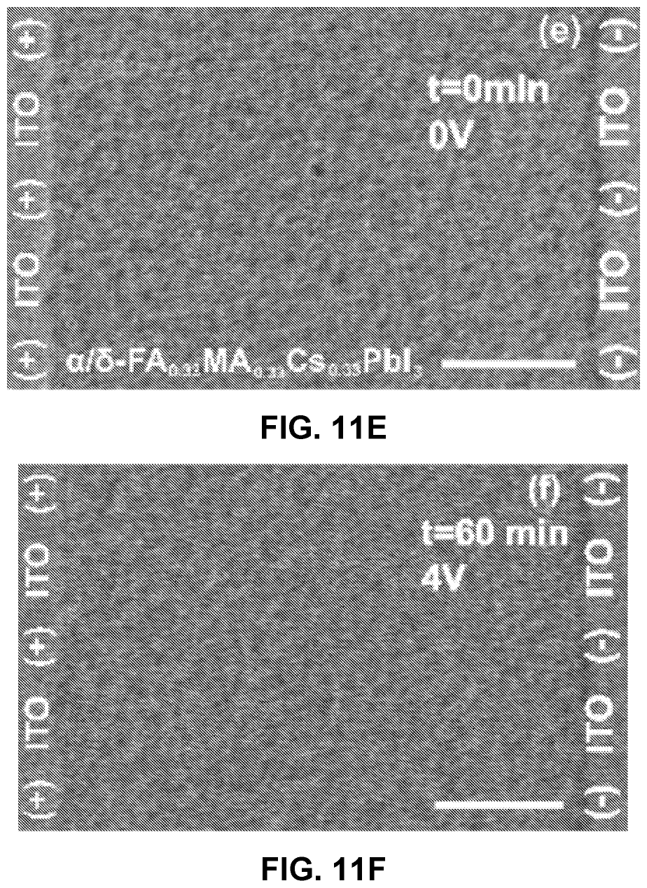

In both binary and triple-cation perovskite phases, post-bias scanning electron microscopy (SEM) images (FIGS. 11A-11F) reveal changes to the perovskite film morphology near positive electrodes, stemming from cation migration, which may indicate that bias-induced A⁺ cation depletion at positive electrodes slowly damages the perovskite.

FIGS. 5G-5H next illustrate α/δ-FA_{0.33}MA_{0.33}Cs_{0.33}PbI₃ lateral device FA⁺ and MA⁺ IR-PHI ratio maps. FIG. 5I shows corresponding average FA⁺ (circles) and MA⁺ (diamonds) line profiles. In contrast to above α-phase lateral devices, no appreciable cation accumulation or depletion occurs at α/δ-FA_{0.33}MA_{0.33}Cs_{0.33}PbI₃ ITO/perovskite interfaces under the same biasing conditions. This suggests the improved stability of mixed α/δ-FAₓMA_{y}Cs_{1-x-y}PbI₃ films against bias-induced cation migration. SEM images after biasing (FIGS. 11A-11F) corroborate this, showing no evidence of film degradation near either positive or negative electrode.

### Infrared Photothermal Heterodyne Imaging (IR-PHI) Method

FAₓMA_{y}Cs_{1-x-y}PbI₃ thin films were produced as previously described above and then deposited onto pre-patterned ITO substrates (FIGS. 8A-8C). Samples were then mounted to a closed loop 3-axis piezo stage (Mad City Labs), coupled to a 2-axis manual micrometer stage (Semprex) on an inverted microscope (Nikon). The output from a pulsed, tunable, IR optical parametric oscillator (OPO) (M Squared; 1040-1840 cm⁻¹, 20 kHz repetition rate) was focused onto samples through their substrates with a 0.65 numerical aperture (NA) reverse Cassegrain reflective objective (Ealing). IR powers were ˜1 mW at the 7 sample, with a spot size of ˜5 μm. The output of a 1064 nm laser from a continuous wave ytterbium fiber laser (IPG Photonics) was used as the probe beam. Probe light was focused onto samples with intensities of order ˜500 kW/cm² using a 0.95 NA refractive objective (Nikon) in a counter-propagating geometry. IR-PHI signals were extracted using a lock-in amplifier (Stanford Research Instruments) at the IR OPO repetition rate. IR-PHI spectra were obtained by measuring IR-PHI responses as functions of IR OPO wavelength.

### 1D Poisson Modeling Method

Voltage profiles of lateral devices are simulated through 1D Poisson modeling. Simulations assume negligible currents due to polarization of the perovskite layer. This stems from MAPbI₃'s low frequency dielectric constant of 25.7. Most of the electrical resistance therefore lies within the perovskite bulk as opposed to perovskite/electrode interfaces. Both the perovskite and ITO are assumed to be p-type with work functions of 4.9 and 4.7 eV respectively. A 0.2 V potential difference, therefore, arises at ITO/perovskite interfaces due to Fermi level equilibration. These simulations reveal nearly constant electric fields throughout perovskite active layers with associated linear potential drops across channels.

### Example 7: Time-of-Flight Secondary Ion Mass Spectrometry (ToF-SIMS) and Photoluminescence (PL) Evaluation of Bias-Induced Cation Migration in Lateral Devices

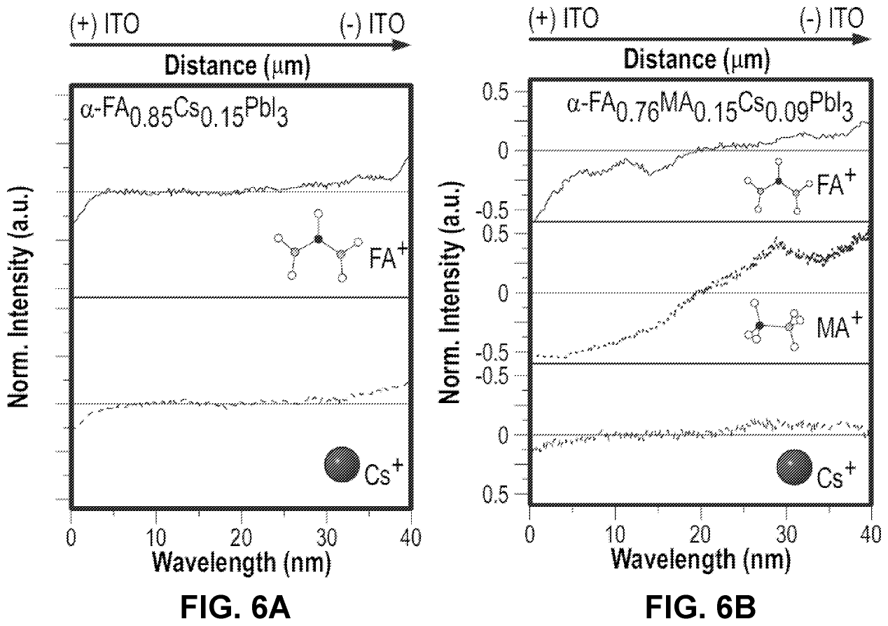

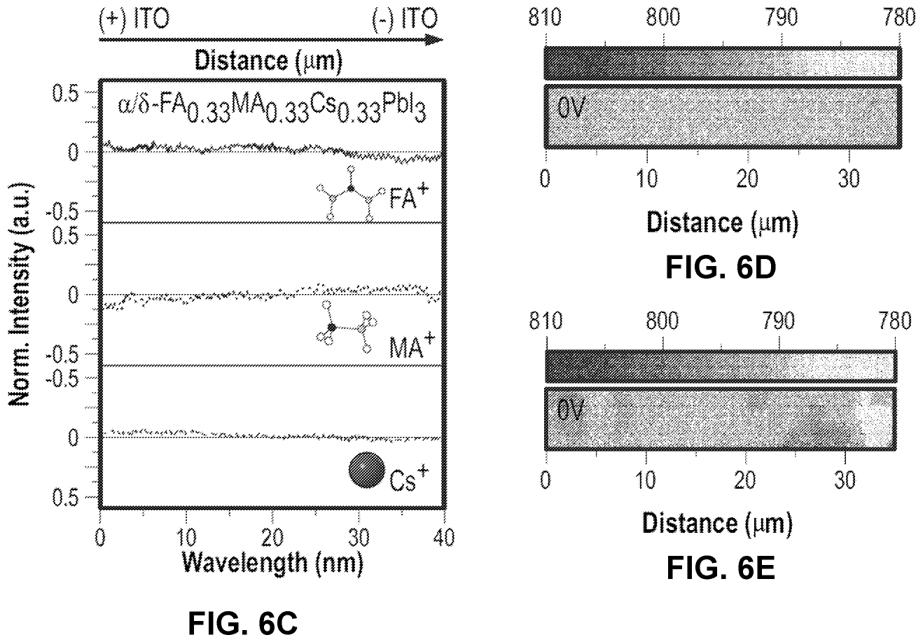

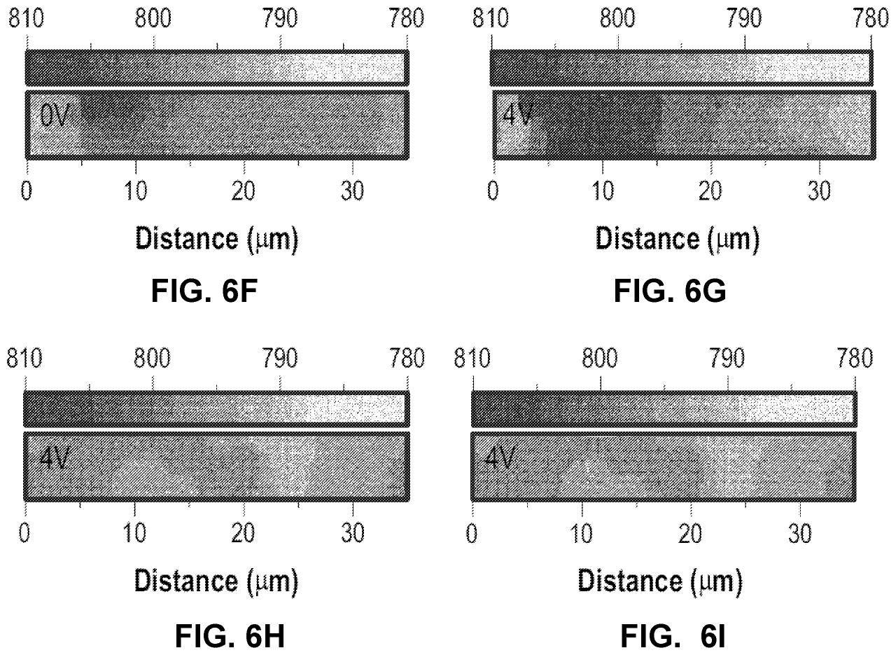

Since IR-PHI cannot monitor Cs⁺ migration, spatially-resolved ToF-SIMS atomic and molecular compositional maps have been acquired for FA_{0.85}Cs_{0.15}PbI₃ (FIG. 6A), FA_{0.76}MA_{0.15}Cs_{0.09}PbI₃ (FIG. 6B) and α/δ-FA_{0.33}MA_{0.33}Cs_{0.33}PbI₃ (FIG. 6C) lateral devices before and after biasing. Grey horizontal lines (where Norm Intensity (a.u.)=0) in FIGS. 6A-6C, are self-ratioed, unbiased ToF-SIMS intensity profiles for all compositions. Graphed against the unbiased Tof-SIMS intensity profiles are graphs depicting the ratios of post bias, cation-specific ToF-SIMS intensity profiles with associated initial (unbiased) intensity profiles for all compositions [FA⁺, MA⁺, and Cs⁺; ITO electrode polarity and direction of cation migration indicated atop FIGS. 6A-6C]. FIGS. 6A-6B demonstrate that for α-phase, double- and triple-cation materials, all three cations accumulate (deplete) at corresponding negative (positive) ITO electrodes. In contrast to either FA_{0.85}Cs_{0.15}PbI₃ or FA_{0.76}MA_{0.15}Cs_{0.09}PbI₃, α/δ-FA_{0.33}MA_{0.33}Cs_{0.33}PbI₃ lateral devices show little to no evidence of FA⁺, MA⁺ or Cs⁺ migration (FIG. 6C). ToF-SIMS compositional measurements on lateral devices corroborate the IR-PHI data in FIGS. 5A-5I and support claims of enhanced α/δ-FA_{0.33}MA_{0.33}Cs_{0.33}PbI₃ stability towards bias-induced, cation migration.

Local photoluminescence (PL) measurements have been carried out to assess the effects of biasing and cation migration on the optical response of each of the hybrid perovskite active layers. Emission wavelength maximum (λ_{PL,max}) maps have therefore been acquired across lateral device channels before and after 60 minutes of biasing at 4 V. FIGS. 6D, 6F, 6H (FIGS. 6E, 6G, 6I) show before (after) λ_{PL,max} maps for FA_{0.85}Cs_{0.15}PbI₃ (FIGS. 6D-6E), FA_{0.76}MA_{0.15}Cs_{0.09}PbI₃ (FIGS. 6F-6G) and α/δ-FA_{0.33}MA_{0.33}Cs_{0.33}PbI₃ (FIGS. 6H-6I) lateral devices. These PL maps reveal 5-10 nm light-shaded shifts and dark-shaded shifts across α-phase active channels following biasing. The shifts are uneven, which can be due to local variations in cation migration activation energies. For FA_{0.85}Cs_{0.15}PbI₃, light-shaded shifts (dark-shaded shifts) are attributable to local increases in Cs⁺ (FA⁺) concentrations. FA_{0.76}MA_{0.15}Cs_{0.09}PbI₃ light-shaded shifts/dark-shaded shifts cannot uniquely be linked to stoichiometric changes given that triple-cation emission energies can arise from a multitude of different compositions (see FIG. 4B). It was observed from these PL measurements that biasing causes no apparent changes to the response of α/δ-FA_{0.33}MA_{0.33}Cs_{0.33}PbI₃ lateral devices. FIGS. 6H-6I show near identical before/after λ_{PL,max} maps. PL, IR-PHI and ToF-SIMS data thus collectively point to the enhanced stability of α/δ-FA_{0.33}MA_{0.33}Cs_{0.33}PbI₃ against bias-induced cation migration.

### Time-of-Flight Secondary Ion Mass Spectrometry (ToF-SIMS) Method

An ION-ToF ToF-SIMS V Time-of-Flight SIMS (ToF-SIMS) spectrometer was used to chemically image perovskite lateral devices, using methods described in prior reports. After brief sputter cleaning of specimens with a 1 keV oxygen ion beam (250×250 μm², 8 nA current), high-resolution imaging was conducted using a 30 keV Bi³⁺ primary ion beam, (0.08 pA pulsed beam current). 60×60 μm² areas were analyzed. Imaging was conducted until the primary ion beam dose density reached 1×10¹³ ions cm⁻² to remain under the static-SIMS limit.

### Photoluminescence (PL) Measurement Method

Perovskite lateral devices were photoexcited using a 520 nm continuous wave (CW) laser (Coherent, Obis), focused onto samples using a high NA objective (Zeiss, 0.65 NA). Samples were raster scanned over 5×45 μm² areas point by point using a three axis, closed loop piezo stage (Mad City Labs) to create an image. At each point, emission was collected with the same objective and a barrier filter was used to reject any scattered laser light. The collected emission was then detected using a fiber-based spectrometer (Ocean Optics) to acquire local spectra on a point by point basis. Spectral parameters (emission maxima, intensities, linewidths) were subsequently extracted via fitting using home-written Python software.

### Example 8: Impact of Bias-Induced Cation Migration on the Operational Stability of Mixed Cation Perovskite Solar Cells

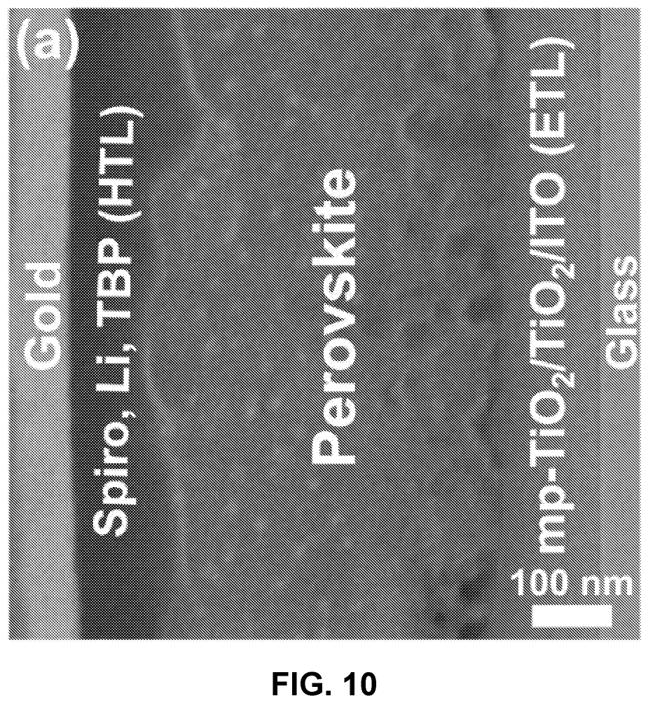

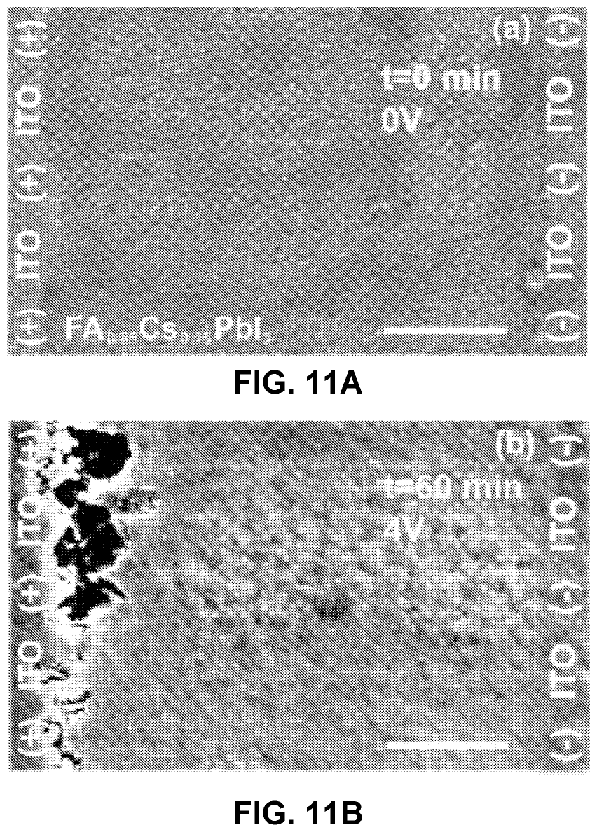

Cation migration and δₒᵣₜₕₒ-CsPbI₃ inclusions impact the stability of double and triple-cation perovskite solar cells. This may be observed by comparing the operational stabilities of FA_{0.76}MA_{0.15}Cs_{0.09}PbI₃ and α/δ-FA_{0.33}MA_{0.33}Cs_{0.33}PbI₃ solar cells. Planar FA_{0.76}MA_{0.15}Cs_{0.09}PbI₃ and α/δ-FA_{0.33}MA_{0.33}Cs_{0.33}PbI₃ solar cells have therefore been manufactured using modified and previously reported solution deposition methods with TiO₂/fluorine-doped tin oxide (FTO) and Spiro-OMeTAD as electron and hole transport layers (ETL and HTL respectively). FIG. 10 shows a cross-sectional SEM image of a resulting α/δ-FA_{0.33}MA_{0.33}Cs_{0.33}PbI₃ solar cell where an average perovskite active layer thickness is 500 nm. TABLE 2 summarizes resulting solar cell figures of note (PCEs, open circuit voltages [V_{OC}], short circuit current densities [J_{SC}], and fill factors [FF]) wherein measured PCEs range from ˜13-19%.

TABLE 2
Triple-cation solar cell figures of note.

| | PCE | V_{OC} | FF | J_{SC} |
|---|---|---|---|---|
| A⁺ Composition | (%) | (mV) | (%) | (mA/cm²) |
| FA_{0.76}MA_{0.15}Cs_{0.09}PbI₃ | 19.06 ± 0.59 | 1030 ± 10 | 76.8 ± 2.2 | 24.10 ± 0.34 |
| α/δ-FA_{0.33}MA_{0.33}Cs_{0.33}PbI₃ | 13.61 ± 0.71 | 990 ± 10 | 63.3 ± 0.3 | 21.73 ± 0.49 |

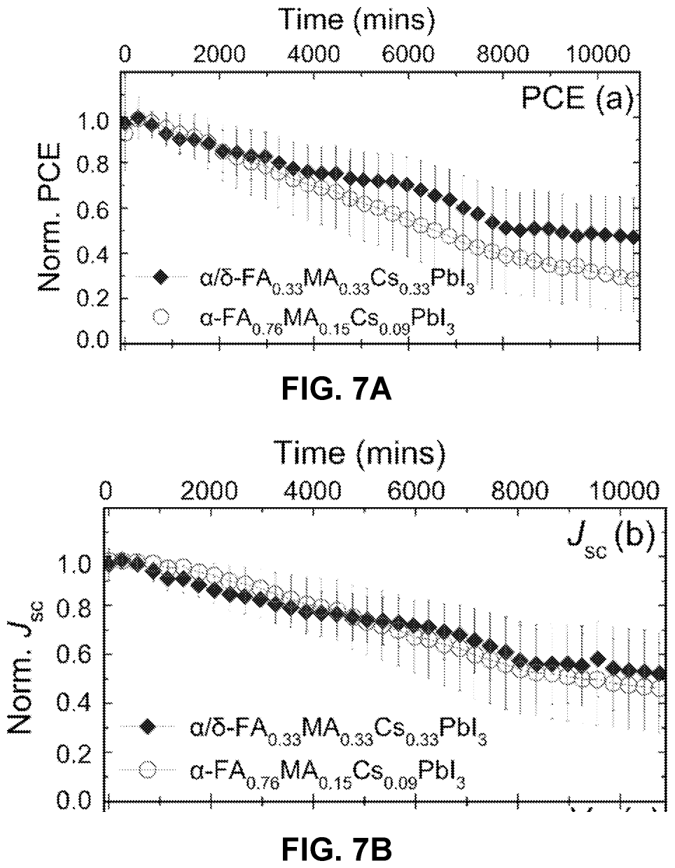

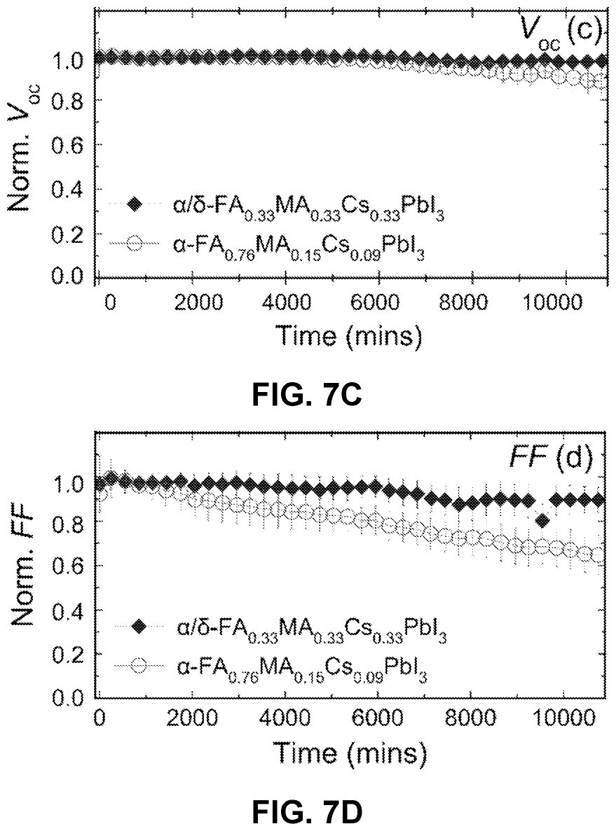

Solar cell stability tests were conducted over the course of ˜11,000 minutes using ISOS-L-1 testing. In these measurements, unencapsulated solar cells are held under constant resistance (510Ω) with 77% simulated solar illumination, a constant temperature of ˜30° C., and a humidity between 20-30%. FIG. 7A shows that average PCE values for FA_{0.76}MA_{0.15}Cs_{0.09}PbI₃ solar cells drop to 35% of their initial value after ˜11,000 minutes. An associated 80% PCE time (τ₈₀) is ˜2640 minutes. α/δ-FA_{0.33}MA_{0.33}Cs_{0.33}PbI₃ solar cells exhibit longer τ₈₀ values with an average of ˜3240 minutes.

FIGS. 7B-7D further reveal concurrent J_{SC}, V_{OC} and FF losses for FA_{0.76}MA_{0.15}Cs_{0.09}PbI₃ devices. Prior studies, investigating the same device architecture, have ascribed this behavior to cation migration and interface specific effects, such as Au electrode diffusion into the device stack. The former leads to cation redistribution near electrodes in the perovskite active layer and detrimentally impact each of the device metrics. This is akin to performance losses seen in mixed halide devices that undergo light-induced halide segregation.

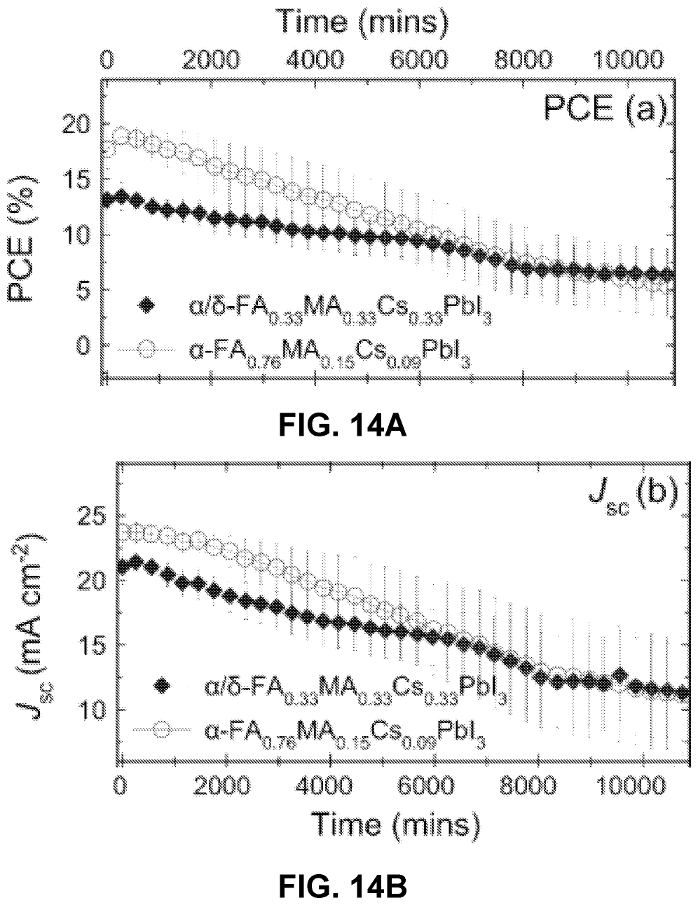

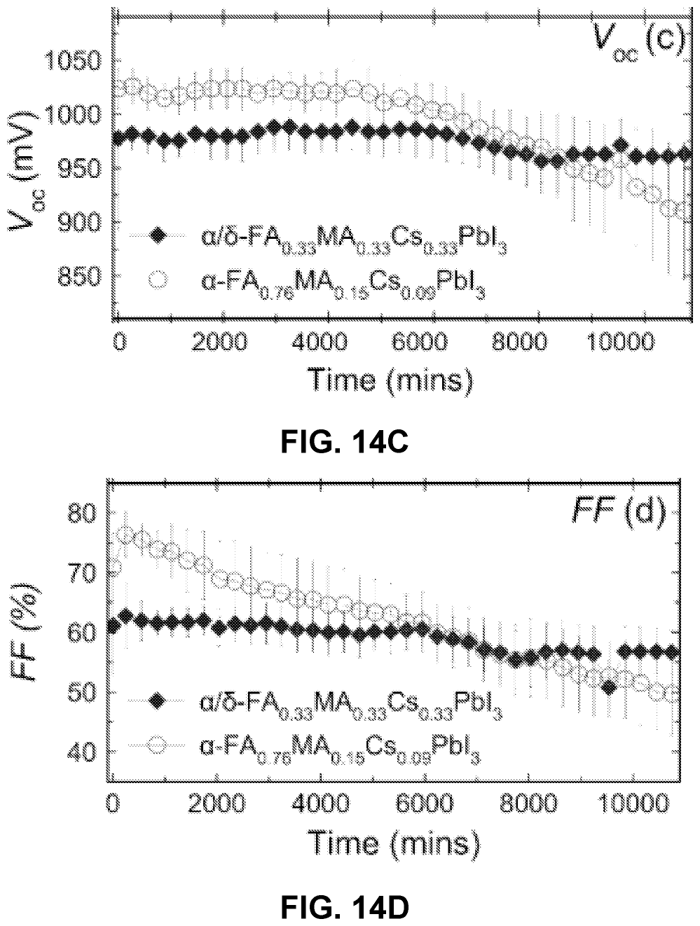

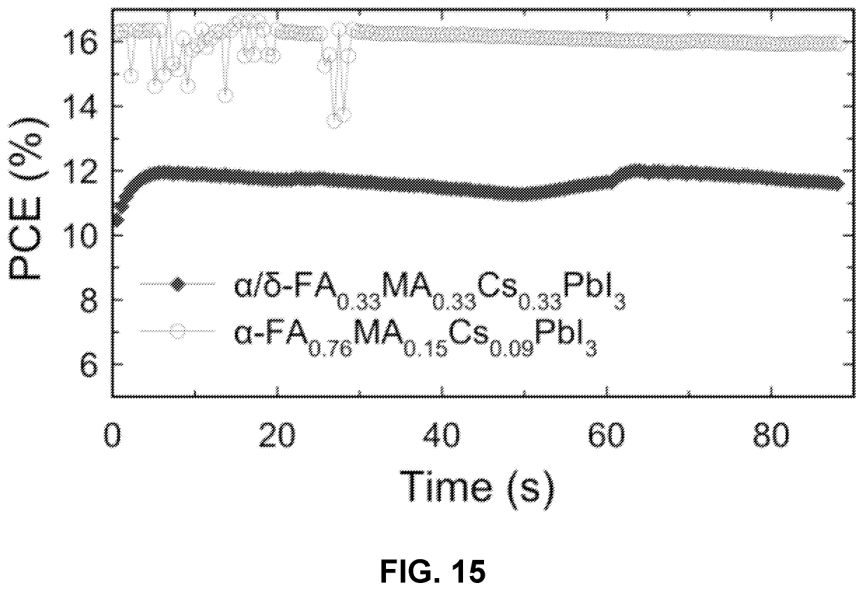

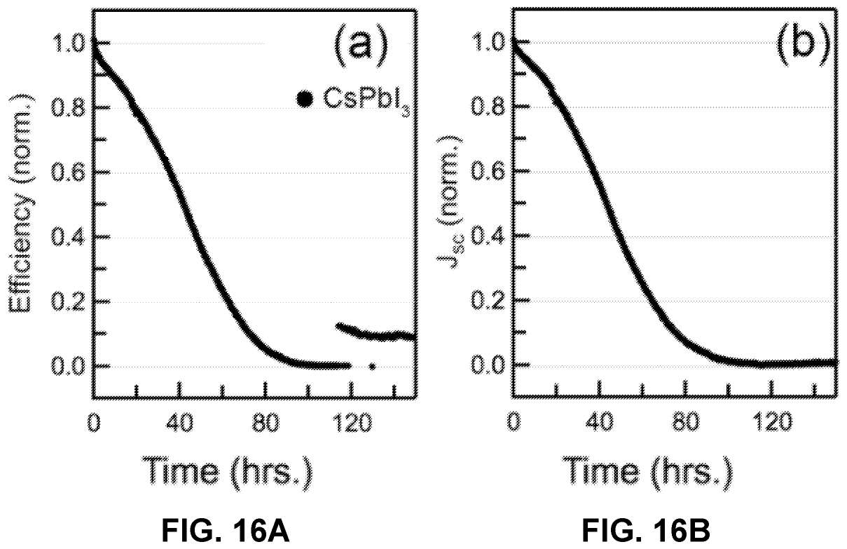

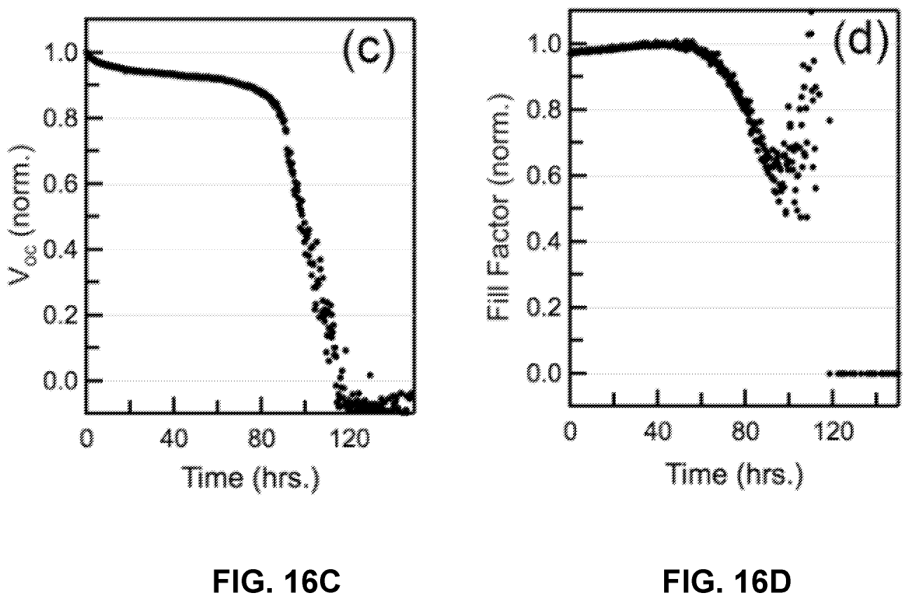

By contrast, V_{OC} and FF remain relatively constant in α/δ-FA_{0.33}MA_{0.33}Cs_{0.33}PbI₃ devices. Only J_{SC} changes during testing. This disparate behavior may stem from the low volume fraction of photoinactive, δₒᵣₜₕₒ-CsPbI₃ inclusions present in films. These inclusions have minimal to no impact on FF and V_{OC} as seen in FIGS. 7C-7D. The J_{SC} decline may originate from reduced carrier generation rates due to absorption losses incurred in α/δ-FA_{0.33}MA_{0.33}Cs_{0.33}PbI₃ during testing. This observation is supported by additional operational stability testing of complementary CsPbI₃ solar cells under N₂ (FIGS. 14A-14D) where both FF and V_{OC} remain stable while J_{SC} losses appear to result from partial active layer phase transformation from black (α-phase) CsPbI₃ to yellow (δₒᵣₜₕₒ-phase) CsPbI₃.

### Solar Cell Fabrication Method

Patterned fluorine-doped tin oxide substrates (Thin Film Devices) were washed by sonication in acetone and isopropanol and then cleaned by UV-ozone treatment for 15 minutes. A TiO₂ electron transport layer was deposited onto cleaned substrates by spin-coating a 0.15 M solution of TAA in butanol with the following program: 700 rpm, 10 s; 1000 rpm, 10 s; 2000 rpm, 30 s. Resulting films were then annealed at 500° C. for 1 hr to form a compact, TiO₂ film approximately 40 nm thick. Immediately before perovskite film deposition, TiO₂ films were cleaned by UV-ozone treatment for 15 minutes and were transferred directly into a nitrogen atmosphere glovebox where perovskite films were deposited as previously described. After annealing perovskite films, substrates were allowed to cool to room temperature for ˜1 minute and then spiro-OMeTAD was deposited atop films by spin-coating at 5000 rpm for 30 s. The spiro-OMeTAD solution used consisted of 72 mg spiro-OMeTAD (0.06 mmol), 28.8 μL TBP (0.2 mmol), and 17.5 μL of a bis(trifluoromethane)sulfonimide lithium salt (LiTFSI) stock solution (520 mg/mL in acetonitrile) dissolved in 1 mL of chlorobenzene. Films were stored in a desiccator overnight and were then completed by the thermal evaporation of 100 nm of Au.

### Device Characterization Method

Solar cell performance was measured under 100 mW cm⁻² simulated AM 1.5 G illumination with an Oriel Sol3A solar simulator, calibrated using an NREL-certified Si 11 reference solar cell. Current density-voltage (J-V) measurements were conducted using a Keithley 2400 source meter.

### Nitrogen Device Stability Testing Method

Solar cells (unencapsulated) were loaded into a home-built degradation setup, dubbed the Stability Parameter Analyzer (SPA). The setup consists of a flow chamber to control the environment of cells (under N₂), electrical housing, and electronics to switch between devices, measure J-V curves and hold devices under resistive load (510Ω), and white light source (white LEDs at 1 sun) to provide constant illumination. Samples were kept at ˜25° C., using an underlying copper tubing filled with circulating water. Every 30 minutes, the system removes the resistive load and takes a J-V scan using a Keithley 2450 source-measure unit. J-V curves were then analyzed to extract relevant parameters. Au was used to improve connectivity of ITO contacts to the electronics.

The foregoing description of the specific aspects will so fully reveal the general nature of the technology that others can, by applying knowledge within the skill of the art, readily modify and/or adapt for various applications such specific aspects, without undue experimentation, without departing from the general concept of the present disclosure. Therefore, such adaptations and modifications are intended to be within the meaning and range of equivalents of the disclosed aspects, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

The breadth and scope of the present disclosure should not be limited by any of the above-described exemplary aspects but should be defined only in accordance with the following claims and their equivalents.

All publications, patents, patent applications, and/or other documents cited in this application are incorporated by reference in their entirety for all purposes to the same extent as if each individual publication, patent, patent application, and/or other document were individually indicated to be incorporated by reference for all purposes.

For reasons of completeness, various aspects of the technology are set out in the following numbered embodiments:

Embodiment 1. A composition comprising:
a layer of formula (A)ₓ(A′)_{y}A″_{(1-x-y)}BX₃, the layer comprising a perovskite and a non-perovskite, wherein:
   A, A′, and A″ comprise (NH₂)₂CH⁺, CH₃NH₃⁺, Cs⁺, Rb⁺, or (NH₂)₂(C═NH₂)⁺, with the proviso that A, A′, and A″ are each different;
   x+y is ≤0.85;
   B is Pb⁺² or Sn⁺²; and
   X₃ comprises I⁻, Br⁻, or combinations thereof.

Embodiment 2. The composition according to embodiment 1, wherein at least one X is I⁻.

Embodiment 3. The composition according to embodiment 1 or 2, wherein at least one X is Br⁻.

Embodiment 4. The composition according to any one of embodiments 1-3, wherein A is (NH₂)₂CH⁺, A′ is CH₃NH₃⁺,

and A″ is Cs⁺.

Embodiment 5. The composition according to any one of embodiments 1-4, wherein B is Pb⁺².

Embodiment 6. The composition according to any one of embodiments 1-5, wherein 0.2≤x≤0.5.

Embodiment 7. The composition according to any one of embodiments 1-6, wherein x is 0.33.

Embodiment 8. The composition according to any one of embodiments 1-7, wherein 0.2≤y≤0.5.

Embodiment 9. The composition according to any one of embodiments 1-8, wherein x is 0.33 and y is 0.33.

Embodiment 10. The composition according to any one of embodiments 1-9, wherein the layer comprises less than 50% of the non-perovskite by volume.

Embodiment 11. The composition according to any one of embodiments 1-10, wherein ion migration is suppressed in the layer.

Embodiment 12. The composition according to any one of embodiments 1-11, wherein the layer has a thickness between 200 nm and 800 nm.

Embodiment 13. A composition comprising:
a perovskite and a non-perovskite, wherein:
   the perovskite comprises AₓA′_{y}A″_{(1-x-y)}BX₃;
   the non-perovskite comprises A″, B, and X;
   A is a first cation, A′ is a second cation, A″ is a third cation, B is a fourth cation, X is an anion;
   the perovskite has a first crystal structure in which the anion is corner-sharing;
   the non-perovskite has a second crystal structure comprising at least one of an orthorhombic structure, a hexagonal structure, or a perovskite-like structure; and
   1−x−y is greater than about 0.15.

Embodiment 14. The composition according to embodiment 13, wherein:
the first cation comprises at least one of methylammonium (MA) or formamidinium (FA);
the second cation comprises at least one of MA or FA; and
the second cation is different than the first cation.

Embodiment 15. The composition according to embodiment 13 or 14, wherein the third cation comprises at least one of cesium or an alkylammonium that is not MA or FA.

Embodiment 16. The composition according to any one of embodiments 13-15, wherein the alkylammonium comprises at least one of guanidinium, dimethylammonium, ethylammonium, or propylammonium.

Embodiment 17. The composition according to any one of embodiments 13-16, wherein:
a total amount is defined as the sum of an amount of an element or a compound present in at least one of the perovskite or the non-perovskite;
   the third cation is present at a molar concentration greater than about 20 mol %; and
   the molar concentration is calculated by dividing a total amount of A″ by the sum of the total amounts of each of A, A′, A″, B, and X.

Embodiment 18. The composition according to any one of embodiments 13-17, wherein x+y is less than about 0.85.

Embodiment 19. The composition according to any one of embodiments 13-18, wherein the perovskite and the non-perovskite are present at a ratio between about 19:1 and about 1:1.

Embodiment 20. The composition according to any one of embodiments 13-19, wherein the first crystal structure comprises at least one of an alpha structure, a beta structure, and or a gamma structure.

Embodiment 21. The composition according to any one of embodiments 13-20, wherein the second crystal structure comprises at least one of an orthorhombic structure, a hexagonal structure, or the perovskite-like structure.

Embodiment 22. The composition according to any one of embodiments 13-21, wherein the perovskite-like structure comprises at least one of a three-dimensional structure (3D-structure), a two-dimensional structure (2D), a one-dimensional structure (1D), or a zero-dimensional structure (0D).

Embodiment 23. The composition according to any one of embodiments 13-22, wherein:
the perovskite comprises MAₓFA_{y}Cs_{(1-x-y)}BX₃;
the non-perovskite comprises CsBX₃;
X comprises a halide; and
x+y is less than about 0.85.

Embodiment 24. The composition according to any one of embodiments 13-23, wherein the halide comprises at least one of iodide, bromide, or chloride.

Embodiment 25. The composition according to any one of embodiments 13-24, wherein B comprises at least one of lead or tin.

Embodiment 26. The composition according to any one of embodiments 13-25, wherein a spatial concentration of at least one of A, A′, or A″ is substantially constant with time when testing the composition positioned between two electrodes and subjected to an applied voltage bias.

Embodiment 27. A solar cell comprising:
a composition comprising:
   a layer of formula (A)ₓ(A′)_{y}A″_{(1-x-y)}BX₃, the layer comprising a perovskite and a non-perovskite, where:
   A, A′, and A″ are each independently (NH₂)₂CH⁺, CH₃NH₃⁺, Cs⁺, Rb⁺, or (NH₂)₂(C═NH₂)⁺, with the proviso that A, A′, and A″ are each different;
   x+y is ≤0.85;
   B is Pb⁺² or Sn⁺²; and
   X₃ comprises I⁻, Br⁻, Cl⁻, or combinations thereof.

Embodiment 28. The solar cell according to embodiment 27, wherein x is 0.33 and y is 0.33.

Embodiment 29. The solar cell according to embodiment 27 or 28, wherein each X is I⁻.

Embodiment 30. The solar cell according to any one of embodiments 27-29, wherein the non-perovskite phase comprises δₒᵣₜₕₒ-phase CsPbI₃.

Embodiment 31. The solar cell, according to any one of embodiments 27-30, wherein the non-perovskite phase prevents ion migration in the layer.

Embodiment 32. The solar cell according to any one of embodiments 27-31, wherein the power conversion efficiency (PCE) is at least 13%.

Embodiment 33. The solar cell according to any one of embodiments 27-32, wherein the fill factor (FF) is at least 60%.

Embodiment 34. The solar cell according to any one of embodiments 27-33, wherein the open-circuit voltage (V_{OC}) is at least 990 mV.

Embodiment 35. The solar cell according to any one of embodiments 27-34, wherein the short-circuit current density (J_{SC}) is at least 20 mA/cm².

1. A composition comprising:
a layer of formula (A)ₓ(A′)_{y}A″_{(1-x-y)}BX₃, the layer comprising a perovskite and a non-perovskite, wherein:
A, A′, and A″ comprise (NH₂)₂CH⁺, CH₃NH₃⁺, Cs⁺, Rb⁺, or (NH₂)₂(C═NH₂)⁺, with the proviso that A, A, and A″ are each different;
x+y is ≤0.85;
B is Pb⁺² or Sn⁺²; and
X₃ comprises I⁻, Br⁻, Cr⁻, or combinations thereof.

2. The composition according to claim 1, wherein at least one X is I⁻.

3. The composition according to claim 1, wherein at least one X is Br⁻.

4. The composition according to claim 1, wherein A is (NH₂)₂CH⁺, A′ is CH₃NH₃⁺, and A″ is Cs⁺.

5. The composition according to claim 1, wherein B is Pb⁺².

6. The composition according to claim 1, wherein 0.2≤x≤0.5.

7. The composition according to claim 6, wherein x is 0.33.

8. The composition according to claim 1, wherein 0.2≤y≤0.5.

9. The composition according to claim 8, wherein x is 0.33 and y is 0.33.

10. The composition according to claim 1, wherein the layer comprises less than 50% of the non-perovskite by volume.

11. The composition according to claim 1, wherein ion migration is suppressed in the layer.

12. The composition according to claim 1, wherein the layer has a thickness between 200 nm and 800 nm.

13. A composition comprising:
a perovskite and a non-perovskite, wherein:
the perovskite comprises AₓA′_{y}A″_{(1-x-y)}BX₃;
the non-perovskite comprises A″, B, and X;
A is a first cation, A′ is a second cation, A″ is a third cation, B is a fourth cation, X is an anion;
the perovskite has a first crystal structure in which the anion is corner-sharing;
the non-perovskite has a second crystal structure comprising at least one of an orthorhombic structure, a hexagonal structure, or a perovskite-like structure; and
1−x−y is greater than about 0.15.

14. The composition according to claim 13, wherein:
the first cation comprises at least one of methylammonium (MA) or formamidinium (FA);
the second cation comprises at least one of MA or FA; and
the second cation is different than the first cation.

15. The composition according to claim 13, wherein the third cation comprises at least one of cesium or an alkylammonium that is not MA or FA.

16. The composition according to claim 15, wherein the alkylammonium comprises at least one of guanidinium, dimethylammonium, ethylammonium, or propylammonium.

17. The composition according to claim 13, wherein:
a total amount is defined as the sum of an amount of an element or a compound present in at least one of the perovskite or the non-perovskite;
the third cation is present at a molar concentration greater than about 20 mol %; and
the molar concentration is calculated by dividing a total amount of A″ by the sum of the total amounts of each of A, A′, A″, B, and X.

18. The composition according to claim 17, wherein x+y is less than about 0.85.

19. The composition according to claim 17, wherein the perovskite and the non-perovskite are present at a ratio between about 19:1 and about 1:1.

20. The composition according to claim 13, wherein the first crystal structure comprises at least one of an alpha structure, a beta structure, and or a gamma structure.

21. The composition according to claim 13, wherein the second crystal structure comprises at least one of an orthorhombic structure, a hexagonal structure, or the perovskite-like structure.

22. The composition according to claim 21, wherein the perovskite-like structure comprises at least one of a three-dimensional structure (3D-structure), a two-dimensional structure (2D), a one-dimensional structure (1D), or a zero-dimensional structure (0D).

23. The composition according to claim 22, wherein:
the perovskite comprises MAₓFA_{y}Cs_{(1-x-y)}BX₃;
the non-perovskite comprises CsBX₃;
X comprises a halide; and
x+y is less than about 0.85.

24. The composition according to claim 23, wherein the halide comprises at least one of iodide, bromide, or chloride.

25. The composition according to claim 23, wherein B comprises at least one of lead or tin.

26. The composition according to claim 13, wherein a spatial concentration of at least one of A, A′, or A″ is substantially constant with time when testing the composition positioned between two electrodes and subjected to an applied voltage bias.

27. A solar cell comprising:
a composition comprising:
a layer of formula (A)ₓ(A′)_{y}A″_{(1-x-y)}BX₃, the layer comprising a perovskite and a non-perovskite, where:
A, A′, and A″ are each independently (NH₂)₂CH⁺, CH₃NH₃⁺, Cs⁺, Rb⁺, or (NH₂)₂(C═NH₂)⁺, with the proviso that A, A′, and A″ are each different;
x+y is ≤0.85;
B is Pb⁺² or Sn⁺²; and
X₃ comprises I⁻, Br⁻, Cl⁻, or combinations thereof.

28. The solar cell according to claim 27, wherein x is 0.33 and y is 0.33.

29. The solar cell according to claim 27, wherein each X is I⁻.

30. The solar cell according to claim 27, wherein the non-perovskite phase comprises δₒᵣₜₕₒ-phase CsPbI₃.

31. The solar cell, according to claim 27, wherein the non-perovskite phase prevents ion migration in the layer.

32. The solar cell according to claim 27, wherein the power conversion efficiency (PCE) is at least 13%.

33. The solar cell according to claim 27, wherein the fill factor (FF) is at least 60%.

34. The solar cell according to claim 27, wherein the open-circuit voltage (V_{OC}) is at least 990 mV.

35. The solar cell according to claim 27, wherein the short-circuit current density (J_{SC}) is at least 20 mA/cm².
